(19) United States
(12) Patent Application Publication
(10) Pub. No.: US 2025/0136386 A1
(43) Pub. Date: May 1, 2025

(54) HIGH THROUGHPUT SUBSTRATE PROCESSING CLUSTER TOOL

(71) Applicant: Applied Materials, Inc., Santa Clara, CA (US)

(72) Inventors: Upendra UMMETHALA, Santa Clara, CA (US); Kaushik ALAYAVALLI, Sunnyvale, CA (US); Ralph LINDENBERG, Büdingen-Rinderbügen (DE); Tuan Anh NGUYEN, San Jose, CA (US); Amit HATTANGADI, Karnataka (IN)

(21) Appl. No.: 18/928,578

(22) Filed: Oct. 28, 2024

Related U.S. Application Data
(60) Provisional application No. 63/665,108, filed on Jun. 27, 2024.

(30) Foreign Application Priority Data
Oct. 28, 2023 (IN) 202341073512

(51) Int. Cl. B65G 47/26; B65G 47/90; H02N 13/00

(52) U.S. Cl. CPC B65G 47/26; B65G 47/907; H02N 13/00; B65G 2201/0297

(57) ABSTRACT

A cluster tool for fabricating substrates includes a factory interface; a first processing mainframe coupled to the factory interface, including: a processing chamber monolithic structure including four processing chambers in the same housing; four load locks coupled to the processing chamber monolithic structure, each load lock including a heater assembly configured to increase the temperature of a substrate disposed in the load lock; and a swapper assembly disposed between the four load locks and the processing chamber monolithic structure, wherein the swapper assembly includes four swappers, each swapper configured to swap substrates between one processing chamber and one load lock along a linear trajectory.

### CROSS-REFERENCE TO RELATED APPLICATIONS

This application claims priority to and the benefit of U.S. Provisional Application No. 63/665,108, filed Jun. 27, 2024. This application also claims priority to and the benefit of under 35 U.S.C. § 119(a) of Indian Provisional Patent Application No. 202341073512, entitled “A High Throughput Substrate Processing Cluster Tool”, which was filed Oct. 28, 2023. Each of the aforementioned applications are incorporated by reference herein in their entirety.

### BACKGROUND

### Field

Embodiments of the present disclosure generally relate to the linear transport of substrates in a cluster tool.

### Description of the Related Art

Cluster tools are used in the manufacturing of semiconductor devices on substrates. Cluster tools have robotic mechanisms that are used to convey substrates between different chambers within the cluster tool. A substrate is placed in a load lock of the cluster tool and then may be transferred between multiple robotic mechanisms before being placed into a processing chamber that deposits or otherwise forms a layer or feature on the surface of the substrate. Additionally, these robotic mechanisms are operated by different motors.

There is a need in the art for a method of rapidly, efficiently and cost effectively transferring substrates from a load lock to a processing chamber. There is also a need in the art to operate multiple robotic mechanisms while reducing the number of motors.

### SUMMARY

In one embodiment, a cluster tool comprises a factory interface; a first processing mainframe coupled to the factory interface, including: a processing chamber monolithic structure including four processing chambers in the same housing; four load locks coupled to the processing chamber monolithic structure, each load lock including a heater assembly configured to increase the temperature of a substrate disposed in the load lock; and a swapper assembly disposed between the four load locks and the processing chamber monolithic structure, wherein the swapper assembly includes four swappers, each swapper configured to swap substrates between one processing chamber and one load lock along a linear trajectory.

In one embodiment, a swapper comprises a body; a first arm rotatable relative to the body, the first arm including a first support; a second arm rotatable relative to the body, the second arm including a second support; an electrostatic chuck assembly, including: a first electrode disposed in the first support; a second electrode disposed in the first support, wherein the first electrode and second electrode are configured to be energized to chuck a first substrate to the first support; a third electrode disposed in the second support; and a fourth electrode disposed in the second support, wherein the third electrode and fourth electrode are configured to be energized to chuck a second substrate to the second support.

In one embodiment, a swapper comprises: a body; a first arm rotatable relative to the body, the first arm including a first support; an electrostatic chuck assembly, including: a first electrode disposed in the first support; a second electrode disposed in the first support; a first rotary electrical connector coupled to the first arm, the first rotary electrical connector configured to supply electrical power to the first electrode; and a second rotary electrical connector coupled to the first arm, the second rotary electrical connector configured to supply electrical power to the second electrode.

In one embodiment, a swapper comprises: a body; a first arm rotatable relative to the body, the first arm including a first support and a first plurality of engagement members protruding from the first support; and a second arm rotatable relative to the body, the second arm including a second support and a second plurality of engagement members protruding from the second support, wherein the first plurality of engagement members and the second plurality of engagement members a surface roughness that exceeds 32 microinches.

In one embodiment, a method of operating a cluster tool comprises: heating a first substrate disposed in a first load lock with one or more first heat sources; heating a second substrate disposed in a second load lock with one or more second heat sources; placing the first substrate on a first arm of a first swapper, the first arm being positioned in a first load lock; placing the second substrate on a second arm of the first swapper, the second arm being positioned within a first processing chamber; placing a third substrate on a third arm of a second swapper, the third arm being located in a second load lock; placing a fourth substrate on a fourth arm of the second swapper, the fourth arm being positioned within a second processing chamber; and operating the first swapper and the second swapper to simultaneously move the first substrate on the first arm into the first processing chamber along a first trajectory, the second substrate on the second arm into the first load lock along a second trajectory, the third substrate on the third arm into the second processing chamber along a third trajectory, and the fourth substrate on the fourth arm into the second load lock along a fourth trajectory.

A cluster tool, including: a factory interface; a first processing mainframe coupled to the factory interface, including: a processing chamber monolithic structure including four processing chambers in the same housing; four load locks coupled to the processing chamber monolithic structure; a swapper assembly disposed between the four load locks and the processing chamber monolithic structure, wherein the swapper assembly includes four swappers, each swapper configured to swap substrates between one processing chamber and one load lock along a linear trajectory.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1A illustrates an isometric view of an exemplary cluster tool used to fabricate substrates, according to embodiments described herein.

FIG. 1B illustrates an isometric view of an exemplary cluster tool used to fabricate substrates in a stacked configuration, according to embodiments described herein.

FIG. 2A illustrates a schematic plan view of an exemplary cluster tool, according to embodiments described herein.

FIG. 2B is a schematic partial cross-sectional view of a swapper assembly, according to embodiments described herein.

FIG. 3 is a schematic partial cross-sectional view of a swapper assembly, according to embodiments described herein.

FIGS. 4A-4G are schematic plan views of exemplary cluster tools, according to embodiments described herein

FIG. 5 is a schematic cross-sectional view of an exemplary cluster tool, according to embodiments described herein.

FIG. 6 is a schematic partial cross-sectional view of a swapper assembly, according to embodiments described herein.

FIG. 7A is a schematic partial cross-sectional view of a swapper assembly, according to embodiments described herein.

FIG. 7B is a partial exploded view of a swapper, according to embodiments herein.

FIGS. 8A-8E illustrate an operational sequence of the swapper shown in FIG. 7A-7B, according to embodiments herein.

FIG. 9A illustrates an exemplary embodiment of a lift assembly that can simultaneously raise and lower a substrate in a chamber, according to embodiments herein.

FIG. 9B illustrates an exemplary embodiment of a chamber with the lift assembly of FIG. 9A that can simultaneously raise and lower a substrate, according to embodiments herein.

FIG. 10 illustrates a flow chart of an exemplary method of operating a cluster tool, according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally provides an apparatus and method for processing substrates using a multi-chamber processing system (e.g., a cluster tool) adapted to process substrates. A cluster tool is a system comprising multiple chambers which perform various functions in the electronic device fabrication process. The cluster tool includes at least two swapping mechanisms operated by the same or different motor assembly to transfer substrates between two chambers within the cluster tool.

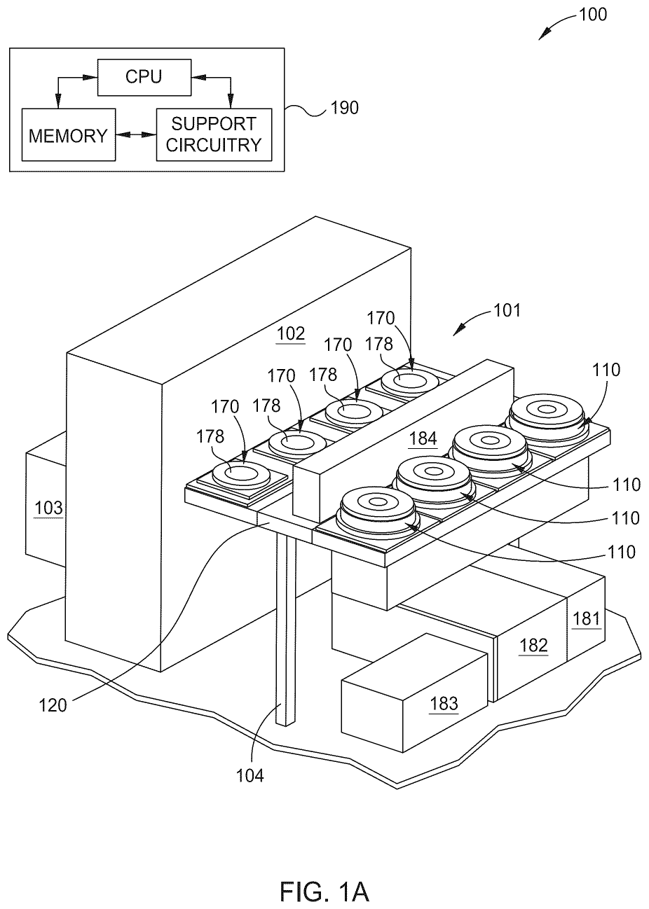

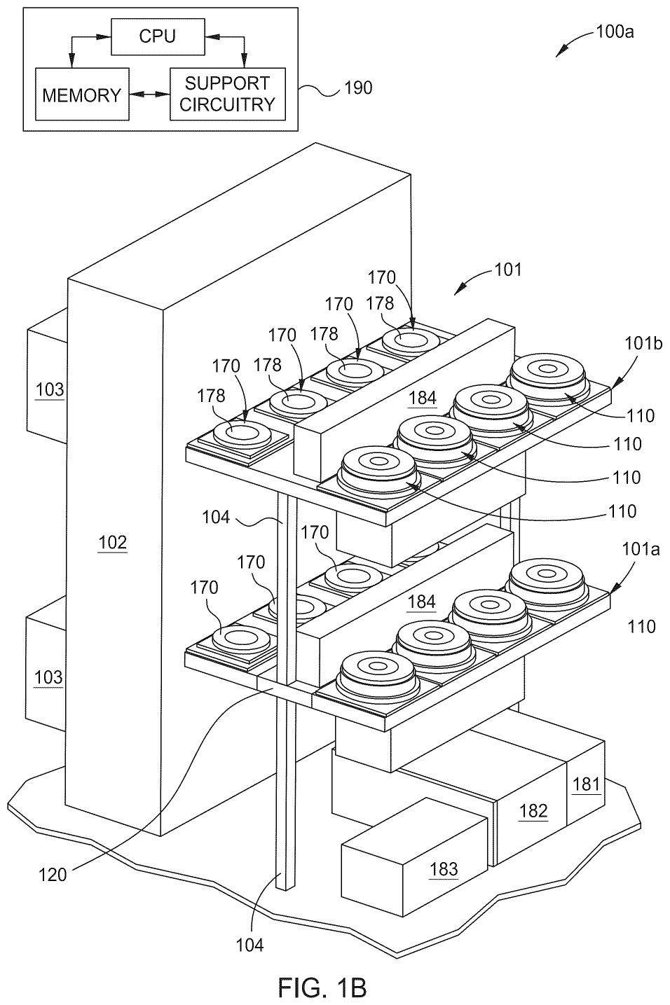

FIG. 1A is an isometric view of a one embodiment of a cluster tool 100 used to fabricate substrates. The cluster tool 100 includes a factory interface 102 and at least one processing mainframe 101.

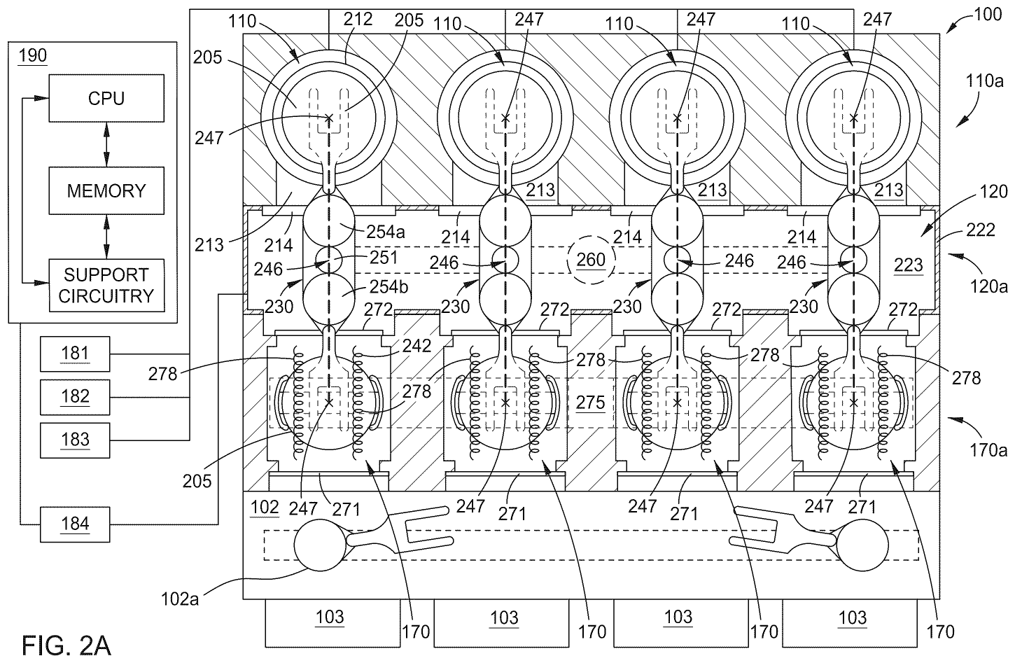

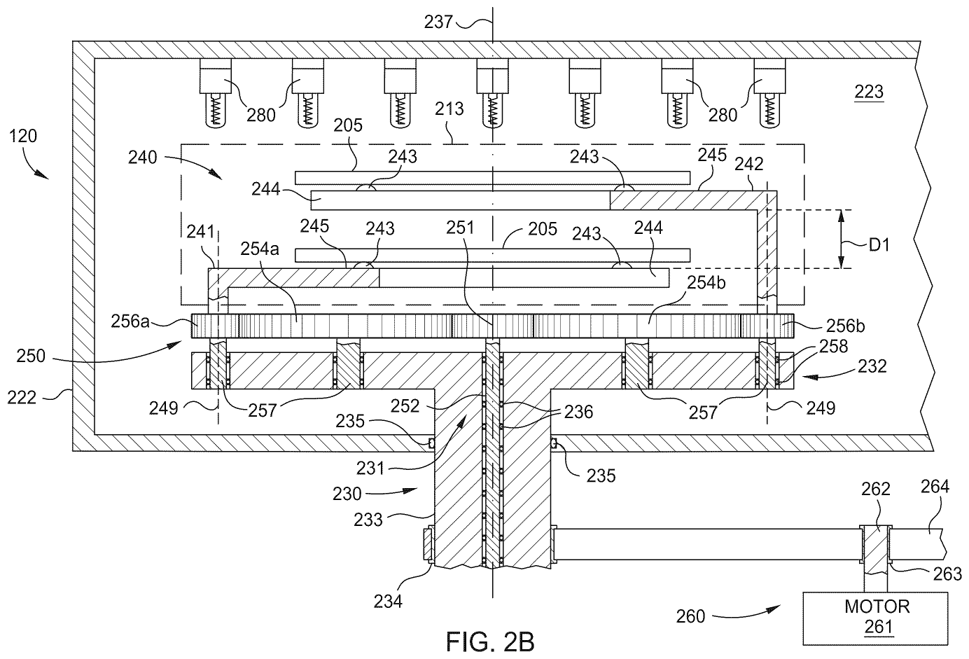

The processing mainframe 101 includes, at least two substrate processing chambers 110, a substrate swapper assembly 120, at least two load locks 170, and a controller 190. While not intended to be limiting as to the scope of the disclosure provided herein, the disclosure provided herein primarily describes an embodiment of the disclosure that includes a processing mainframe 101 that includes, at least four substrate processing chambers 110, a substrate swapper assembly 120, at least four load locks 170, and a controller 190. The load locks 170 and processing chambers 110 can be grouped in pairs, with each grouping having one load lock 170 opposing a corresponding processing chamber 110. The substrate swapper assembly 120 is located between the processing chambers 110 and the load locks 170. The substrate swapper assembly 120 includes a swapper (such as swapper 230 in FIG. 2A) for each pair of the processing chambers 110 and load locks 170, and each swapper is used to swap (e.g., move) substrates (see substrate 205 in FIG. 2A) between the corresponding processing chamber 110 and load lock 170. The processing mainframe 101 may be supported in a position relative to the factory interface 102 by one or more supports 104, which may be a frame, used to support the weight of the processing mainframe 101.

As shown in FIG. 1A, the processing mainframe 101 includes four processing chamber 110 and load lock 170 pairs. In some embodiments, the processing mainframe 101 may have only one processing chamber 110 and load lock 170 pair. In some embodiments, the processing mainframe 101 may have two or three processing chamber 110 and load lock 170 pairs. In some embodiments, the processing mainframe 101 may have more than four processing chamber 110 and load lock 170 pairs, as illustrated in FIG. 1A. In some embodiments, the processing mainframe 101 may have more than five processing chamber 110 and load lock 170 pairs or six processing chamber 110 and load lock 170 pairs.

The processing chambers 110 include a substrate support (e.g., pedestal, platen) and a processing kit and source assembly configured to process the substrate within the processing chamber 110. The processing chambers 110 may perform any number of processes such as preclean, chemical vapor deposition (CVD), plasma enhanced chemical vapor deposition (PECVD), physical vapor deposition (PVD), atomic layer deposition (ALD), decoupled plasma nitridation (DPN), rapid thermal processing (RTP), ashing, annealing, and etching, or any processing chamber utilized in electronic device fabrication. In one embodiment, the processing sequence is adapted to form a high-K capacitor structure, where processing chambers 110 may be a DPN chamber, a CVD chamber capable of depositing poly-silicon, and/or a MCVD chamber capable of depositing titanium, tungsten, tantalum, platinum, or ruthenium.

In some embodiments, the processing chamber 110 includes one or more lift pins. The lift pins are coupled to the substrate support. The substrate is transferred from the swapper to the lift pins. The lift pins then transfer the substrate to the substrate support. In some embodiments, the substrate support is raised to sealingly engage with the process kit assembly to form an isolated processing region around the substrate where the substrate is subjected to a process, such as a PVD process. Once the process is complete, the substrate support is lowered and the substrate is disengaged from the substrate support by the lift pins. The substrate is then transferred from the lift pins and onto the swapper, such as by placing a support surface of the swapper underneath the substrate and retracing the lift pins.

The factory interface 102 may be coupled to one or more front opening unified pods (FOUPs) 103. FOUPs 103 may each be a container having a stationary cassette therein for holding multiple substrates. FOUPs 103 may each have a front opening interface configured to be used with factory interface 102. Factory interface 102 may have a buffer chamber (not shown) and one or more robot assemblies 102a configured to transfer substrates via linear, rotational, and/or vertical movement between FOUPs 103 and the load locks 170. The factory interface 102 may include a set of FOUPs 103 and corresponding one or more robot assemblies 102a for each processing mainframe 101.

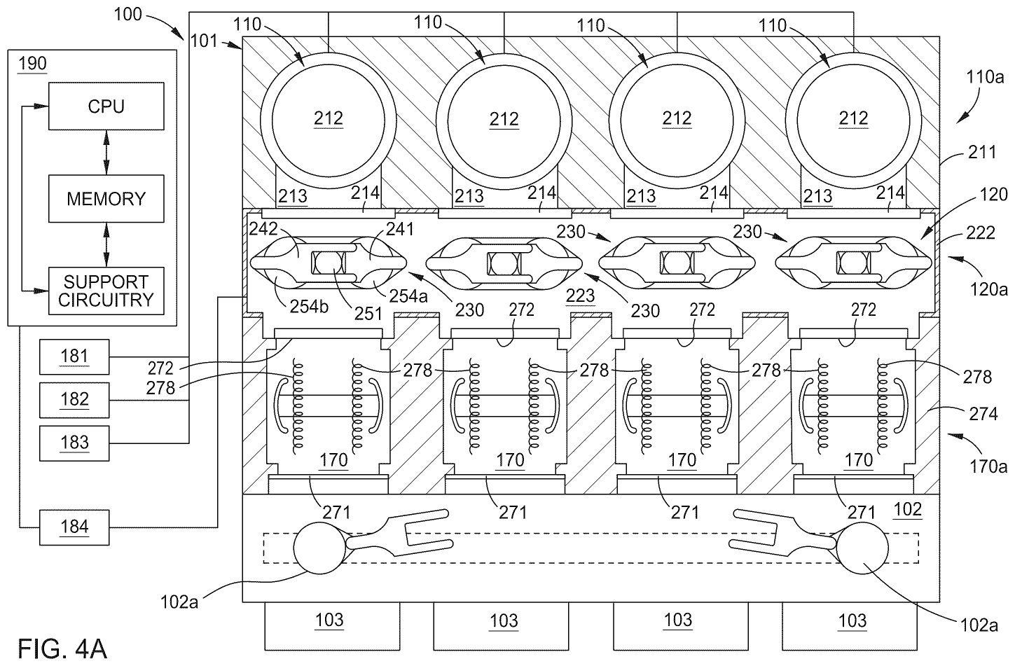

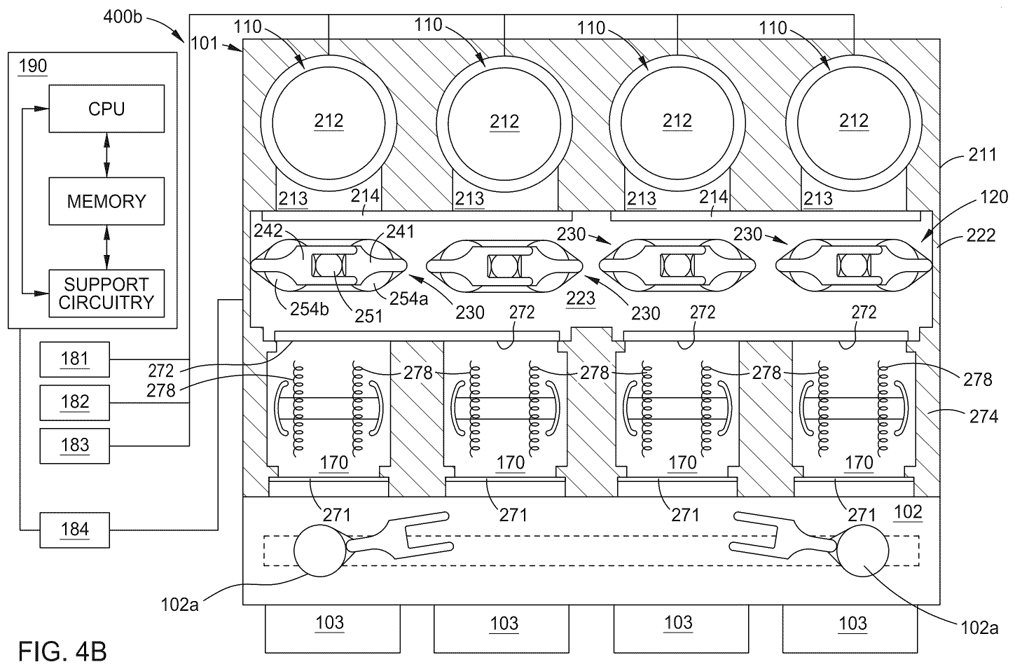

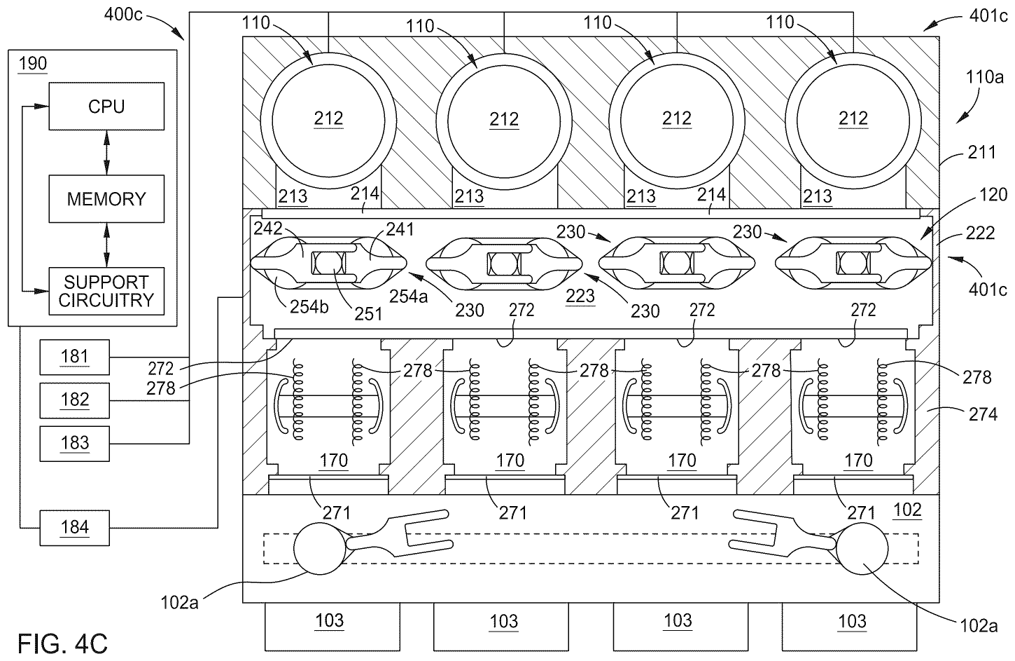

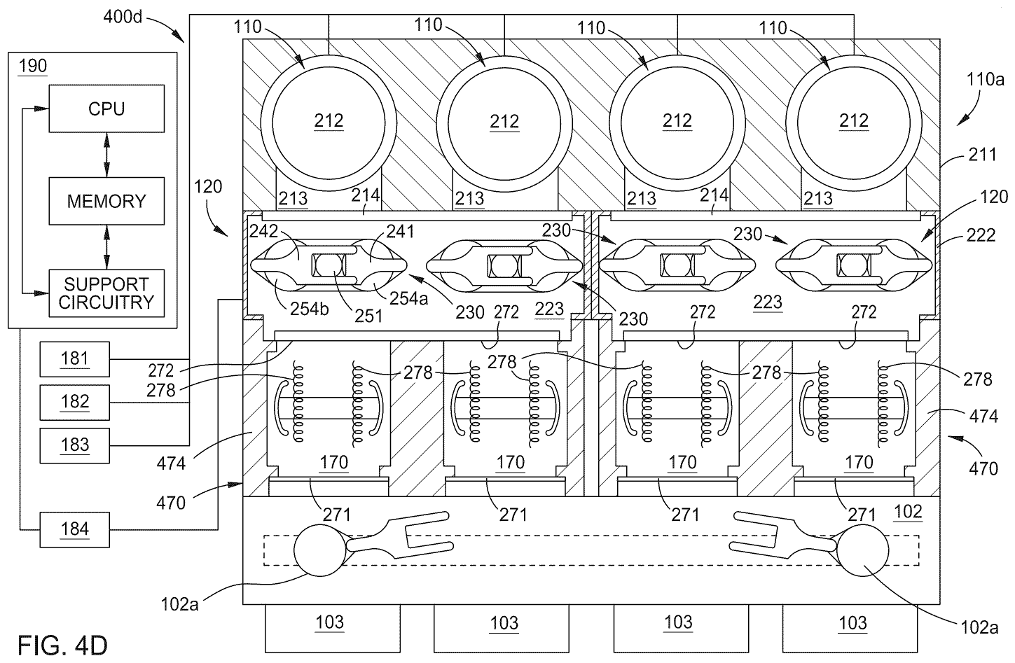

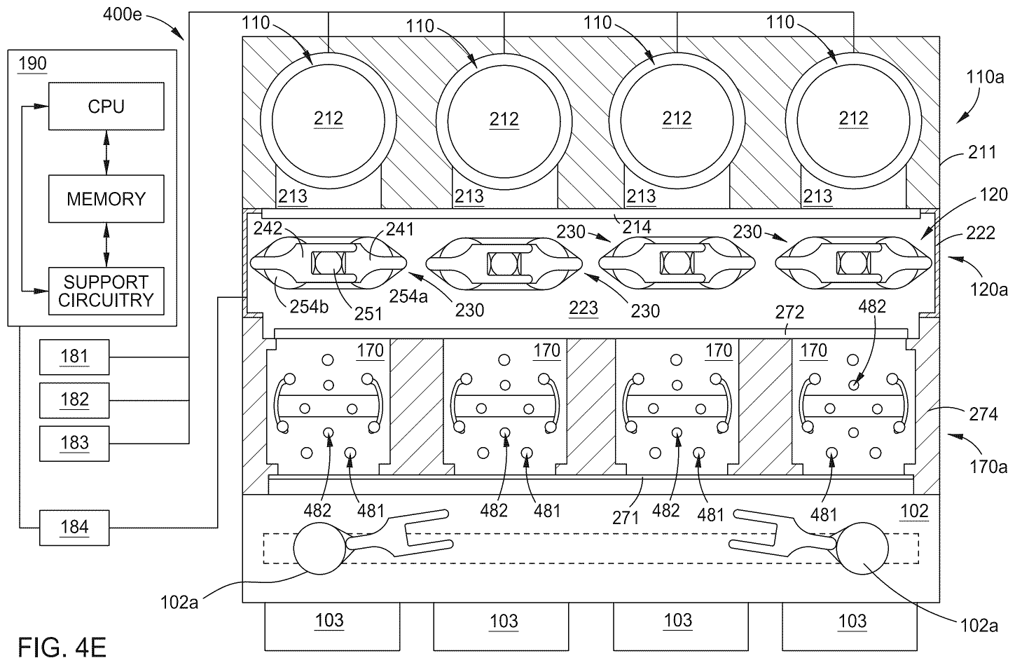

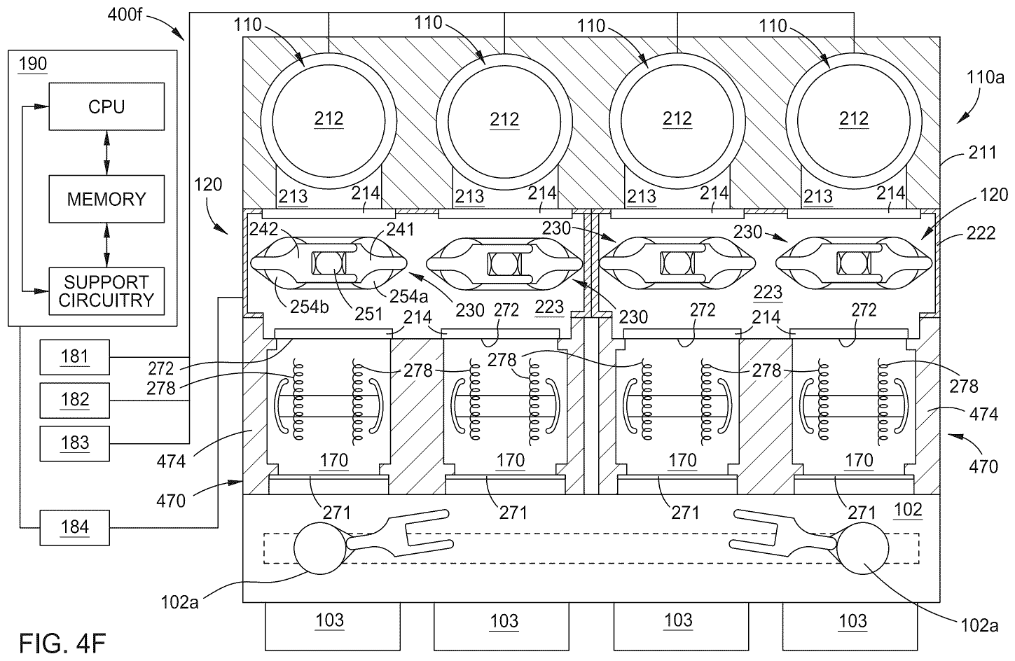

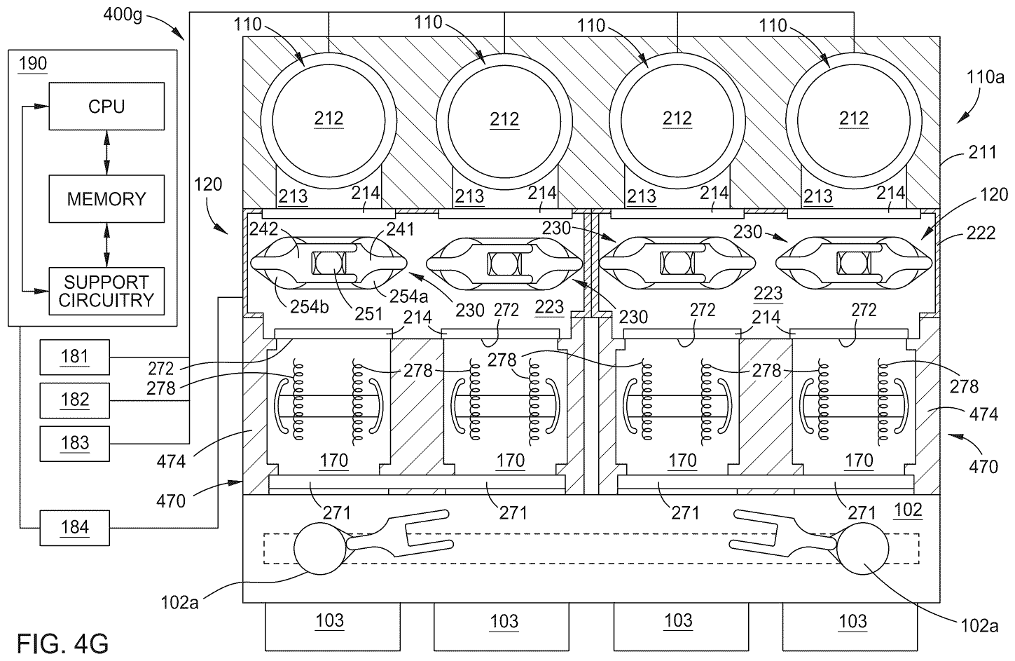

In some embodiments, each swapper 230 (FIGS. 2A and 4A-4G) in the swapper assembly 120 swaps the substrate in each load lock 170 and the processing chamber 110 pair in a linear trajectory. Thus, each substrate is not transferred between multiple robotic arms to transfer the substrate from the load lock 170 to the processing chamber 110, which increases the throughput of the cluster tool 100 as compared to conventional cluster tools that require multiple transfer steps to move a substrate into a processing chamber.

Additionally, the swapper assembly 120 may have one motor assembly 260 (FIG. 2A) that includes a single motor that is used to operate all the swappers 230 simultaneously. Thus, one motor assembly may be used to cause the swapping of the substrates in all the pairs of processing chambers 110 and load locks 170 of each processing mainframe 101. In some embodiments, each swapper of the swapper assembly 120 is operated by a different motor assembly, and is thus operated by one or more different motors. Thus, the swapper assembly 120 may have four motors that correspond with the four swappers. In some embodiments, two or more swappers of the swapper assembly share a motor assembly, thus sharing one motor, while the remaining swappers are operated by one or more different motor assemblies. For example, the swapper assembly 120 may have four swappers, and two swappers of the swapper assembly 120 may be operated by a first motor assembly with a first motor while the other two swappers are operated by a different motor assembly with a second motor.

In some embodiments, the processing chambers 110 are part of a monolithic structure, such as sharing a common housing. In some embodiments, the swapper assembly 120 and the load locks 170 may each be part of a separate monolithic structure. Thus, in this case, the processing mainframe 101 may be formed by connecting a monolithic structure including the processing chambers 110 to one side of the monolithic structure of the swapper assembly 120 and then also connecting a monolithic structure including the load locks 170 to the other side of the monolithic structure including of the swapper assembly 120. Assembling the cluster tool 100 from monolithic structures, each including multiple components, such as processing chambers 110, load locks 170, or swapper assembly 120, decreases manufacturing and assembly costs and reduces the number of leak points. In some other embodiments, the processing chambers 110, the swapper assembly 120 and the load locks 170 may each be part of a single monolithic structure that is used to support and provide a positional reference for the mounting and aligning of the various components to each other and to the monolithic structure.

The cluster tool 100 may also include a pumping system 181, a gas panel 182, a power supply 183, and an electronics module 184. The pumping system 181, gas panel 182, and power supply 183 are shown disposed underneath of the processing mainframe 101. The pumping system 181 is used to create and/or maintain a pressure within each processing chamber 110. For example, the pumping system 181 may be a vacuum pump or a plurality of vacuum pumps used to evacuate the processing chambers 110. The gas panel 182 may include one or more gases used to process a substrate in the processing chamber. The power supply 183 may be a power source, such as an AC power source or a DC power source, to operate electrical equipment of the cluster tool 100, such as operating equipment in the processing chamber 110, such as the source assembly. The power supply 183 may also include an optional RF power supply for the processing chambers 110, such as supplying RF power to a shower head or an electrostatic chuck of the processing chamber. The electronics module 184 may include electronics used to monitor and control the cluster tool 100. The electronics module 184 may be in communication with the controller 190.

In some embodiments, the pumping system 181 is also used to create and maintain a pressure within the load locks 170, such as being used to evacuate each load lock 170. The pumping system 181 may also be used to create and maintain a pressure within the swapper assembly 120, such as being used to evacuate the swapper assembly 120. In some embodiments, the cluster tool 100 includes a separate pumping system 181 for each of the processing chambers 110, the swapper assembly 120, and the load locks 170.

In some embodiments, there is a pressure gradient in the processing mainframe 101. For example, the magnitude of the vacuum within the processing mainframe 101 may increase from the load lock 170 (highest pressure) to the interior of the processing chambers 110 (lowest pressure). The pumping system 181 may be used to maintain the pressure gradient.

In some embodiments, the pumping system 181 may include one or more abatement modules to remove or break down chemicals or materials in the fore line to increase vacuum (e.g., exhaust) pump longevity.

In some embodiments, each load lock 170 may include a heater assembly 178. The heater assembly 178 includes one or more heat sources, such as heat sources 278 shown in FIG. 2A, that are positioned in the load lock 170 to be above the substrate. The heat sources 278 may include radiant heat sources such as lamps, for example halogen lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein. In some embodiments, the heater assembly 178 may be used to pre-heat the substrate. In some embodiments, the heater assembly 178 may be used for a degas operation. The pumping system 181 connected to each load lock 170 may be used to remove emissions from the substrate during degassing.

FIG. 1B illustrates an isometric view of one embodiment of a cluster tool 100a used to fabricate substrates. Cluster tool 100a is similar to cluster tool 100 shown in FIG. 1, except that it includes multiple processing mainframes 101 in a stacked configuration, such as first processing mainframe 101a and a second processing mainframe 101b. The second processing mainframe 101b is supported above the first processing mainframe 101a by one or more supports 104.

As shown in FIG. 1B, the factory interface 102 has a set of FOUPs for both the first processing mainframe 101a and the second processing mainframe 101b. In some embodiments, the cluster tool 100 has a plurality of processing mainframes 101 while the factory interface 102 has one set of FOUPs and a corresponding set of robot assemblies 102a to transfer the substrates to and from the FOUPs to the load locks 170 of the plurality of processing mainframes 101.

The controller 190 may include a programmable central processing unit (CPU) which is operable with a memory (e.g., non-transitory computer readable medium and/or non-volatile memory) and support circuits. The support circuits are coupled to the CPU and includes cache, clock circuits, input/output subsystems, power supplies, and the like, and combinations thereof coupled to the various components of the cluster tool 100, to facilitate control of the cluster tool 100. For example, in one or more embodiments the CPU is one of any form of general purpose computer processor used in an industrial setting, such as a programmable logic controller (PLC), for controlling various polishing system components and sub-processors. The memory, coupled to the CPU, is non-transitory and is one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates the operation of the cluster tool 100. The instructions in the memory are in the form of a program product such as a program that implements the methods of the present disclosure (e.g., middleware application, equipment software application, etc.). The program code may conform to any one of a number of different programming languages. In one or more embodiments, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

The various methods (such as operations 1001-1012) and operations disclosed herein may generally be implemented under the control of the CPU of the controller 190 by the CPU executing computer instruction code stored in the memory (or in memory of a particular processing chamber) as, e.g., a software routine. When the computer instruction code is executed by the CPU, the CPU controls the components of the cluster tool 100 to conduct operations in accordance with the various methods and operations described herein. In one or more embodiments, the memory (a non-transitory computer readable medium) includes instructions stored therein that, when executed, cause the methods (such as the operations 1001-1012) and operations (such as the operations 1001-1012) described herein to be conducted. The operations described herein can be stored in the memory in the form of computer readable logic.

FIG. 2A illustrates a schematic plan view of an exemplary embodiment of cluster tool 100 shown in FIG. 1A. As shown, the cluster tool has four load locks 170, four processing chambers 110, and four swappers 230 disposed in the swapper assembly 120 configured to swap substrates 205 between each pair of load locks and processing chambers 110.

Each processing chamber 110 may include a substrate support 212. The substrate support 212 may include one or more lift pins to lift and lower the substrate 205 relative to the substrate support 212, such as using the lift pins to transfer the substrate 205 to or from the swapper 230. In some embodiments, a slit valve 214 is located between the processing chamber 110 and the swapper assembly 120. When the slit valve 214 is in an open position, the swapper 230 is allowed to enter the processing chamber 110 through the opening 213 (e.g., tunnel) that leads to the interior of the processing chamber 110. When the slit valve 214 is in the closed position, the opening 213 is covered and the processing chamber 110 is isolated from the swapper assembly 120. In some embodiments, the slit valve 214 is omitted from the system.

In some embodiments, each processing chamber 110 may be contained in the same monolithic housing 211. Thus, processing chambers 110 are part of a monolithic processing chamber structure 110a that can be attached to the swapper assembly 120 on the side opposite from the load locks 170. In some embodiments, the processing chambers 110 do not all share the same housing. For example, each processing chamber 110 may have separate housing 211. In some embodiments, starting from the left-hand side of FIG. 2A, the two left-most processing chambers 110 may share a housing 211 and the two processing chambers 110 may share a separate housing 211.

Each load lock 170 may have a first slit valve 271 and a second slit valve 272. When the first slit valve 271 is open, a substrate 205 can be transferred from the factory interface 102 and to support members, such as lift pins, positioned in the load lock 170. When the first slit valve 271 is closed, the interior of the load lock 170 is isolated from the factory interface 102. Thus, the load locks 170 provide a vacuum interface between the factory interface 102 (e.g., front-end environment) and the remainder the cluster tool 100. When the second slit valve 272 is open, the swapper 230 is allowed to enter the load lock 170 where the substrate 205 is then transferred to the swapper 230. When the second slit valve 272 is closed, the interior of the load lock 170 is isolated from the swapper assembly 120 and the processing chambers 110. In some embodiments, the first slit valves 271 may be disposed at an angle relative to the factory interface to facilitate allowing a robot of the factory interface 102 to enter the load lock 170 to receive the substrate 205 from the swapper 230.

The four load locks 170 are shown contained in the same housing 274. Thus, the load locks 170 are part of a monolithic load lock structure 170a that can be attached to the factory interface 102 and also attached to the swapper assembly 120 on the side opposite of the processing chambers 110. In some embodiments, the load locks 170 do not all share the same housing. For example, each load lock 170 may have separate housing. In some embodiments, starting from the left-hand side of FIG. 2A, the two left-most load locks 170 may share a housing 274 and the two right-most load locks 170 may share a separate housing.

In some embodiments, the four load locks 170 share a lift 275, as shown in FIG. 2A, disposed underneath the housing 274. The lift 275 is configured to raise and lower the lift pins of the load locks 170 in unison. These lift pins are engageable with the substrate 205 to facilitate handing the substrate 205 off to the robotic arm of the factory interface 102 or the swapper 230. Thus, the lift 275 can control the simultaneous transfer of a substrate 205 onto or from either the robotic assemblies 102a of the factory interface 102 or the swapper 230.

The lift 275 may be a plate that extends underneath the chamber of the load locks 170 connected to the lift pins. An actuator, such as a hydraulic, pneumatic, or electric actuator, may be used to move the plate axially to change the position of the lift pins. In some embodiments, each load lock 170 has a separate lift 275. As shown, each load lock 170 includes one or more heat sources 278 of the heater assembly 178 disposed in the upper part of the load lock 170 above the substrate 205. FIG. 2A shows the heat sources 278 as resistive heat sources.

FIGS. 2A and 2B illustrate an exemplary embodiment of the swapper assembly 120, with FIG. 2B showing a schematic partial side cross-sectional view of the swapper assembly 120 (i.e., far right side of FIG. 2A). The swapper assembly 120 additionally includes a housing 222 and a motor assembly 260. The housing 222 defines an internal swapper chamber 223. The swappers 230 are partially disposed in the swapper chamber 223, and the substrates pass through the swapper chamber 223 between the load locks 170 and the processing chamber 110. Each swapper 230 may be operated by the same motor assembly 260 which is located outside of the swapper chamber 223, such as being disposed underneath the swapper chamber 223 as shown in FIG. 2A.

In some embodiments, each swapper 230 is in the same swapper chamber 223. In some embodiments, a wall of the housing 222 bifurcates the swapper chamber 223 such that each swapper 230 is isolated from the other or isolates a pair of swappers 230 from another pair of swappers 230.

In some embodiments, all four swappers 230 are disposed in the same housing 222. Thus, the swapper assembly 120 may be part of a monolithic swapper assembly structure 120a that is attachable to the monolithic load lock structure 170a.

FIGS. 2A-2B illustrate an exemplary embodiment of the swappers 230. Only one swapper 230 (left-most swapper 230 in FIG. 2A) is fully labeled for clarity. However, this swapper 230 is representative of all the other swappers 230. Each swapper 230 includes a body 231 (e.g., base) that includes an upper portion 232 and a shaft 233 that extends downward from the upper portion 232. The shaft 233 includes a body pulley 234. A seal element 235 may be disposed around the shaft 233 to seal the swapper chamber 223 from the outside environment while facilitating the rotation of the body 231 relative to the housing 222. The upper portion 232 supports an arm assembly 240 and a gear assembly 250 of the swapper 230. The arm assembly 240 includes a first arm 241 (e.g., left arm) and a second arm 242 (e.g., right arm) that are rotated by the gear assembly 250. The arms 241, 242 are moveable to extended positions where each arm 241, 242 is located within either the load lock 170 or the processing chamber 110 to convey a substrate 205 disposed on the arm 241, 242. FIG. 2A shows the first arm 241 in an extended position, with the first arm 241 positioned within the processing chamber 110 above the substrate support 212 while the second arm 242 is shown in an extended positioned within the load lock 170. The arms 241, 242 are moved to swap positions, such that the first arm 241 is moved to an extended position within the load lock 170 while the second arm 242 is moved to an extend position within the processing chamber 110. The arms 241, 242 may also be moved to a retracted position (FIG. 2B) where the arms 241, 242 overlap one another.

The arms 241, 242 each include a swapper blade 244, or sometimes referred to herein as a blade 244 (or support), that includes a support surface 245. As shown in FIG. 2A, the blade 244 may have a fork shape. One prong of the fork may be shorter than the other prong, or both prongs may have the same length. The substrate 205 is placed into engagement with a support surface 245 of the blade 244. The blade 244 carries the substrate 205 disposed thereon as the swapper 230 moves the substrate 205 between the load lock 170 and the processing chamber 110.

The blade 244 includes one or more, such as three, engagement members 243 protruding from the blade 244. For example, the engagement members 243 may be protruding dimples. The substrate 205 is in contact with the engagement members 243 when disposed on the blade 244, which reduces the area of contact between the substrate 205 and the blade 244. In other words, the support surface 245 of the blade 244 is the area of contact between the substrate 205 and the engagement members 243. The engagement members 243 may be made from or coated with a material having a high coefficient of friction. For example, the engagement members 243 may have a surface roughness that exceeds 32 microinches. For example, the engagement members 243 may have a surface roughness between 45 microinches and 65 microinches.

As shown in FIG. 2B, the blade 244 of the first arm 241 and second arm 242 are located at different heights such that one arm can pass underneath the other arm without the substrate 205 on the lower arm contacting the upper arm. As shown, the first arm 241 is located at a height above the upper portion 232 that is lower than the second arm 242. A distance, shown as D1, is present between the support surface 245 of the blade 244 of the first arm 241 and the underside of the second arm 242. This distance D1 is sized to allow the substrate 205 to pass underneath the second arm 242 without contacting the second arm 242. Additionally, the opening between the load lock 170 and the swapper assembly 120 that can be covered by the second slit valve 272 is sized to allow the arms 241, 242 to enter and exit the load lock 170 without the arms 241, 242 or the substrate 205 disposed thereon contacting a surface of the opening. The opening 213 (shown as dashed opening) between the processing chamber 110 and the swapper assembly 120 that can be covered by the slit valve 214 is also sized to allow the arms 241, 242 to enter and exit the processing chamber 110 without the arms 241, 242 or the substrate 205 disposed thereon contacting a surface of the opening 213.

FIG. 2A shows a substrate 205 placed on the blade 244 of each arm 241, 242. A portion of each arm 241, 242 is shown in dashed to illustrate that the substrate 205 is supported on the corresponding arm 241, 242. An illustrative trajectory point 247 is shown for each blade 244. The trajectory point 247 will follow the trajectory 246 as the motor assembly 260 operates the swapper 230 to move the arms 241, 242. The trajectory point 247 is shown being between the two forks of the blade 244, but the trajectory point 247 may be located at a point on the support surface 245 depending on the shape of the blade 244. In some embodiments, the trajectory 246 (shown as a line) is a substantially linear path that extends from the center point of the substrate support 212, over the central axis 237 of the swapper 230, to a center point of the load lock 170. In other words, this illustrative point 247 moves linearly as the first arm 241 and second arm 242 swap positions. The substrate 205 disposed on the blade 244 of each arm 241, 242 similarly moves in a linear fashion along the trajectory 246. Thus, the swapper 230 is used to move the substrates in a linear trajectory between the load lock 170 and processing chamber 110, and vice versa. The arms 241, 242 move the substrate 205 disposed thereon along parallel linear trajectories that are separated by a distance since each arm is located at a different height. And, as shown in FIG. 2A, each pair of processing chambers 110 and load locks 170 are positioned opposing each other across the swapper assembly 120 such that the linear trajectory of the substrates 205 moved by one swapper 230 is parallel to the linear trajectory of the substrates 205 moved by the other swapper 230.

Referring back to FIG. 2B, the gear assembly 250 includes a central gear 251, a first idler gear 254a, a second idler gear 254b, and a first arm gear 256a, and a second arm gear 256b. The first arm 241 is attached to the first arm gear 256a and the second arm 242 is attached to the second arm gear 256b. The central gear 251 is shown as stationary. For example, the central gear 251 may be fixed on a shaft 252, as shown in FIG. 2B, that extends through the upper portion 232 and the shaft 233 of the body 231. The body 231 may include one or more bearing elements 236 to facilitate the rotation of the body 231 relative to the stationary shaft 252. The bearing elements 236 may be a ball bearing, a spherical roller bearing, or other bearing element suitable to facilitate rotation between the body 231 and the shaft 252. The idler gears 254a,b and arm gears 256a,b may be mounted on a shaft 257 that is coupled to the upper portion 232. For example, a plurality of bearing elements 258 (similar to bearing elements 236) are embedded in the upper portion 232 to facilitate the rotation of the shaft 257, and thus the rotation of the gear attached to the corresponding shaft 257, relative to the body 231. In some embodiments, the shaft 257 is fixed to the body 231 and a plurality of bearing elements 258 are disposed around the shaft 257 between the corresponding gear and the shaft 257.

FIG. 2B shows the motor assembly 260 connected with one swapper 230, which is representative of the connection of the motor assembly 260 with the other swappers 230 shown in FIG. 2A. The motor assembly 260 includes a single motor 261 that rotates an output shaft 262. In other words, the motor assembly 260 may include one, and only one, motor 261 to operate multiple swappers 230 instead of using different motor to operate each swapper 230 in some embodiments. The output shaft 262 includes a motor pulley 263. A belt 264 is connected to the motor pulley 263 and loops around the body pulley 234 of each swapper 230. The belt 264 transfers rotational power from the motor pulley 263 to each body pulley 234, which causes the body 231 to rotate about a central axis 237 of the swapper 230. In some embodiments, the motor 261 may be an electrical, hydraulic, or pneumatic motor. In some embodiments, the body pulleys 234 and motor pulley 263 may each have a groove that corresponds with the shape of the belt 264. In some embodiments, the body pulleys 234 and motor pulley 263 may each have teeth that interface with the teeth of the belt 264. In some embodiments, the belt 264 may be substituted for a chain, with the motor pulley 263 and body pulleys 234 being substituted for a sprocket that interfaces with the chain.

In some embodiments, each swapper 230 is operated by a separate motor assembly 260 with a separate motor 261. In some embodiments, pairs of swappers 230 are operated by separate motor assemblies 260. For example, starting from the left-hand side of FIG. 2A, the two left-most swappers 230 may be operated by a first motor assembly 260 while two right-most swappers 230 may be operated by a second motor assembly 260.

As the body 231 of the swapper 230 rotates, the idler gears 254a,b rotate (e.g., orbit) around the stationary central gear 251. The central gear 251 has teeth that interface with corresponding teeth on the idler gears 254a,b. The engagement of the central gear 251 with the orbiting idler gears 254a,b causes the idler gears 254a,b to rotate relative to the body 231 in a first direction. These idler gears 254a,b also have teeth that interface with the teeth of the arm gears 256a,b to cause the arm gears 256a,b to rotate relative to the body 231 in a second direction. The rotation of the arm gears 256a,b causes the corresponding arm 241, 242 attached thereto to rotate relative to the body 231 about an axis 249.

The gear ratio of the gear assembly 250 is configured to achieve a desired shape and resolution of the trajectory (e.g., path) in which the substrate 205 is transferred between the load lock 170 and processing chamber 110. In some embodiments, the gear ratio for the central gear 251 to the arm gears 256a,b is a 1:2 ratio to achieve the linear movement of the substrate 205 by moving the point 247 of the blade 244 along the linear trajectory 246 as shown in FIG. 2A. In other words, one full orbit of an idler gear 254a,b around the central gear 251 causes the corresponding arm gear 256a,b to rotate twice.

The controller 190 can be in communication with the motor assembly 260 to control the position of the arms 241, 242 of the swappers 230. Operating all the swappers 230 with the same motor assembly 260 allows every swapper 230 to be moved in a synchronous fashion. In some embodiments, the swappers 230 are arranged as shown in FIG. 2A where the arms 241, 242 of one swapper 230 move synchronously with the corresponding arm 241, 242 of the other swapper 230. In some embodiments, the swappers 230 are offset to one another. For example, one swapper 230 may have both arms 241, 242 in an extended position while the arms 241, 242 of the other swapper 230 are positioned in the retracted position.

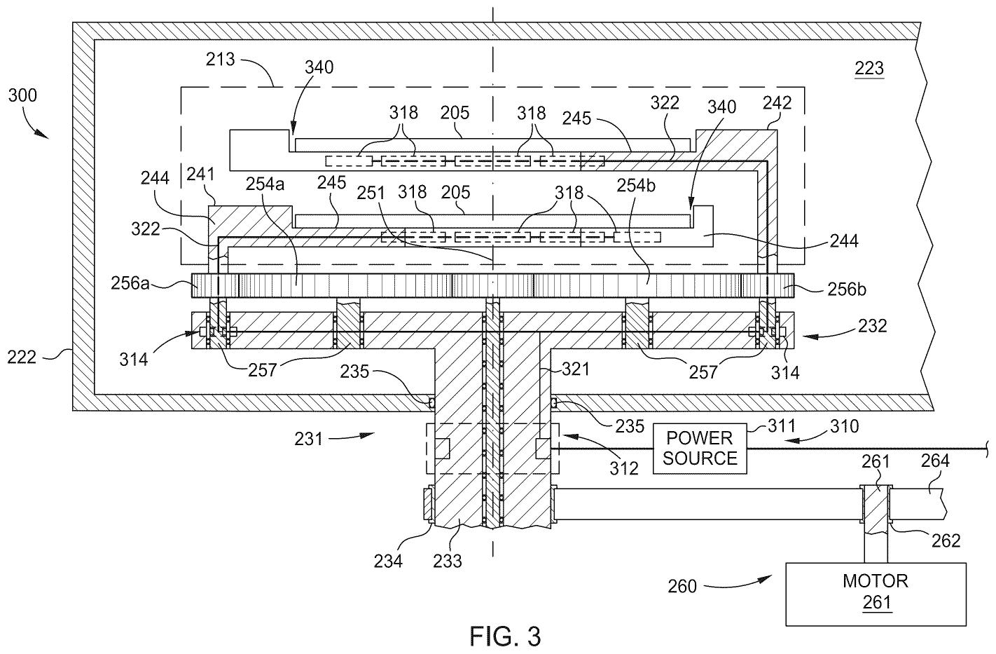

In some embodiments, the swapper assembly 120 may optionally be a pre-heater such that the temperature of the substrates 205 is increased prior to the substrate being placed into the processing chamber 110. The substrate 205 may be pre-heated by radiative heating, convection, or conduction. One or more heat sources 280 may be disposed within the swapper chamber 223 above each swapper 230 that are used to increase the temperature of the substrates 205. The heat sources 280 discussed herein include radiant heat sources such as lamps, for example halogen lamps. The present disclosure contemplates that other heat sources may be used (in addition to or in place of the lamps) for the various heat sources described herein. For example, resistive heaters, light emitting diodes (LEDs), and/or lasers may be used for the various heat sources described herein. In some embodiments, the substrate 205 may be heated by injecting a heated inert gas into the swapper assembly 120. In some embodiments, the arms 241, 242 of each swapper may include embedded heating elements (see FIG. 3) to selectively heat a substrate 205 disposed on one of the arms 241, 242. In some embodiments, the swapper assembly 120 includes the heat sources 280 in addition to the heater assembly 178 in the load lock 170.

In some embodiments, the swapper assembly 120 may also be configured to cool, in addition to pre-heating, the substrates. The cooling can be accomplished by radiative cooling, convection, or conduction. For example, a cooled inert gas may be injected into the swapper assembly 120 to cool one substrate on one arm of the swapper 230 while the other arm of the swapper 230 is being pre-heated. For example, each arm 241, 242 of the swapper 230 may have one or more cooling channels formed therein such that a cooling fluid may be circulated through one of the arms 241, 242 to cool the substrate 205 disposed thereon.

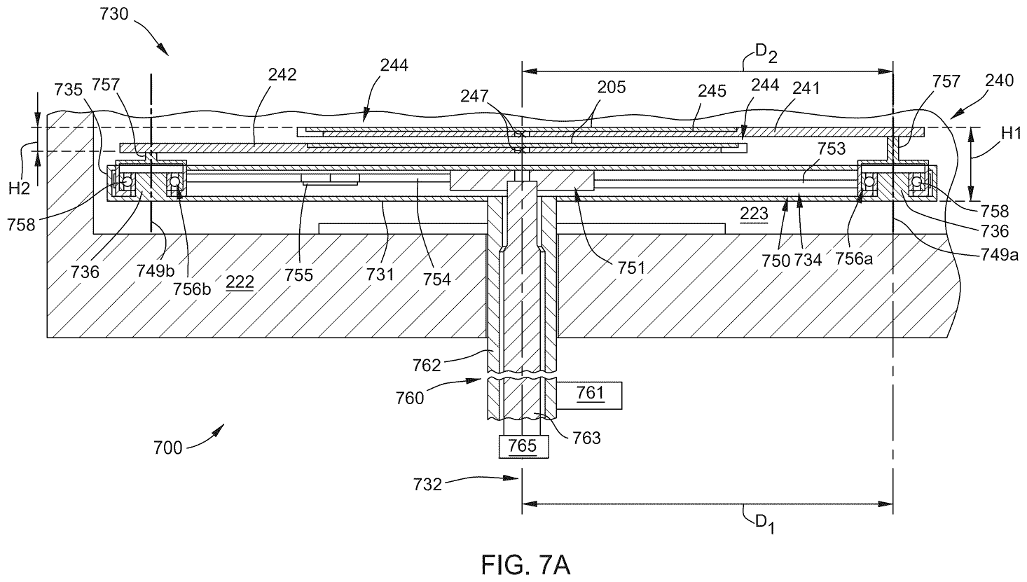

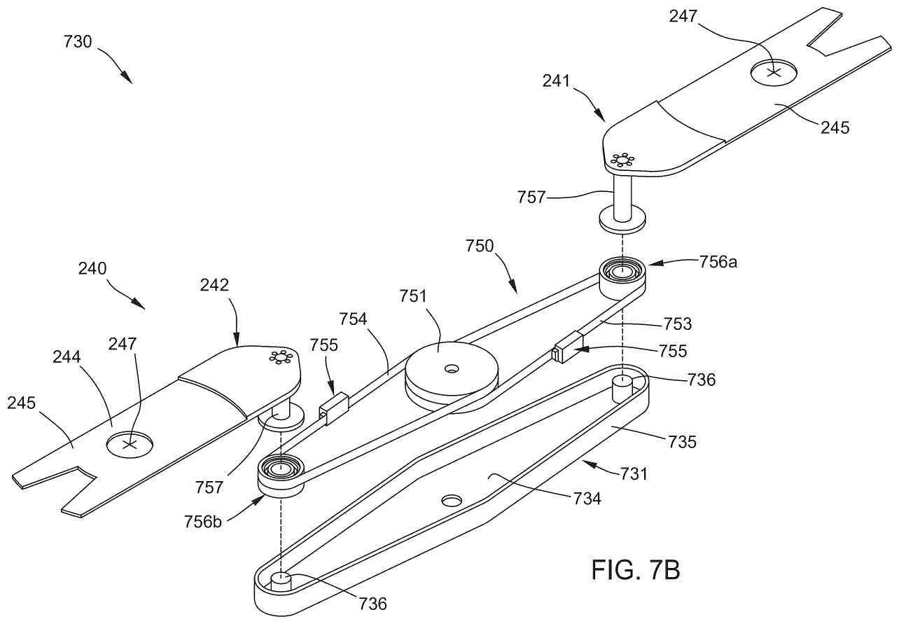

While FIG. 2A-2B illustrate a swapper 230 with a gear assembly 250, the swapper 230 may be of another suitable design. For example, the swapper 230 may include one or more band or pulley systems used to actuate the arms 241, 242 to swap the substrates 205. FIGS. 7A-7B illustrate an exemplary embodiment of a pulley-type swapper.

The motor assembly 260 may be operated move the substrates 205 through the swapper chamber 223 over a period of time sufficient to heat the substrates 205 to a desired temperature. For example, the motor assembly 260 may be used to pause (e.g., stop) the movement of the swappers 230 while the substrates 205 are positioned in the swapper chamber 223 underneath the heat sources 280 for a period of time.

In some embodiments, the motor assembly 260 includes a second belt. The output shaft 262 includes a second pulley and the central gear 251 is coupled to a pulley. The second belt is extends from the second pulley of the output shaft 262 to the pulley coupled to the central gear 251 to rotate the central gear 251 relative to the body 231.

In some embodiments, the cluster tool includes five or more pairs of load locks 170 and processing chambers 110, and one swapper assembly 120 with a swapper 230 located between each pair of load locks 170 and processing chambers 110. The same motor assembly 260 may be used to operate each swapper 230, such as five or more swappers 230. For example, the swapper assembly 120 may have six swappers 230 driven by the same motor assembly 260.

Additionally, while the trajectory 246 shown in FIG. 2A is substantially linear, the swapper 230 can be used to move the substrate 205 along any suitable trajectory, including trajectories that are partially non-linear. For example, the trajectory may be made up of a plurality of trajectory segments, with some segments being at an angle to others, including some segments being linear segments while other segments are an arcuate path. However, each swapper 230 can be operated simultaneously to swap substrates 205 between pairs of load locks 170 and processing chambers 110.

The controller 190 may be used to control the swapper 230 such that the substrates 205 move along a desired velocity and/or acceleration profile as the substrate moves along the trajectory, such as trajectory 246. For example, the controller 190 may coordinate the movement of the components of the swapper 230 to move the substrate 205 along the desired velocity and/or acceleration profile. The velocity and/or acceleration profile may be selected to avoid causing the substrate 205 to move relative to the support 245 as the arms 241, 242 move. In some embodiments, the swapper 230 is operated to move each substrate 205 along a constant or substantially constant speed along the desired trajectory, even though one or more components of the swapper 230 may be changing velocity and/or acceleration. For example, the controller 190 may selectively change the angular accelerations of the arms 241, 242 as the arms 241, 242 rotate about the respective axis 249 to move the substrate 205 along the trajectory at a constant speed or relatively similar speed.

FIG. 3 illustrates a schematic partial cross-sectional view of a swapper assembly 300 which may be substituted for the swapper assembly 120 of the cluster tool 100. The swapper assembly 300 has similar components as the swapper assembly 120 as indicated by the reference signs without reciting the description of these components of the swapper assembly 120 for brevity.

Rather than including a plurality of heat sources 280 above the swappers 230, the swapper assembly 300 pre-heats the substrates 205 by heating the arms 241, 242 using a pre-heat assembly 310. The pre-heat assembly 310 includes a power source 311, a first rotary electrical connector 312 coupled to the shaft 233, second rotary electrical connectors 314 coupled to the upper portion 232, and one or more heating elements 318 disposed in the blade 244 of each arm 241, 242. FIG. 3 is representative of the other swappers 230 with a pre-heat assembly 310 of the swapper assembly 300, and each pre-heat assembly 310 of the multiple swappers 230 may share the same power source 311.

The power source 311 may be a direct current (DC) power supply and the first rotary electrical connector 312 may be a slip ring having a plurality of brush connections or a roll ring connector. The power source 311 may receive power from the power supply 183 or may be power supply 183. Electrical power is transferred from the first rotary electrical connector 312 to the second rotary electrical connectors 314 by a first wire 321. The second rotary electrical connectors 314 may also be a slip ring having a plurality of brush connections or a roll ring connector. The second rotary electrical connectors 314 are shown coupled to the shaft 257 of each arm gear 256a,b. Electrical power is transferred from each second rotary electrical connector 314 to the heating elements 318 in a corresponding arm 241, 242 by a second wire 322.

The blade 244 of each arm 241, 242 may be made of a ceramic material. The plurality of heating elements 318 are embedded in the blade 244. For example, the heating elements 318 may be resistive heating elements. Electrical power supplied to the heating elements 318 is used to generate heat, which is transferred to the substrate 205 in contact with the blade 244. The blade 244 may be sized such that a majority of the underside of the substrate 205 is in direct contact with the support surface 245 to more evenly heat the substrate 205. In some embodiments, more than 80% of the surface area of the underside of the substrate 205 is in contact with the substrate support surface 245. The blade 244 may have a plurality of slots or openings to allow a corresponding lift pin of the processing chamber 110 to access the underside of the substrate 205 that is being pre-heated on the blade 244.

In some embodiments, and as shown in FIG. 3, the blade 244 of each arm 241, 242 includes a pocket 340. The pocket 340 is recessed portion of the arms 241, 242 configured to receive the substrate 205. The lower surface of the pocket 340 is the support surface 245. The pocket 340 prevents the substrate 205 from sliding off the arm 241, 242 during operation of the swapper 230.

In some embodiments, the pre-heat assembly 310 has one second rotary electrical connector 314 that is connected to heating elements 318 embedded in one of the arms 241, 242. For example, the swapper 230 may be operated such that the one of the arms 241, 242 conveys unprocessed substrate 205 to the processing chamber while the other arm 241, 242 is used to convey processed substrates 205. Thus, the arm conveying the unprocessed substrates 205 may be the arm having heating elements 318 embedded therein.

While FIG. 3 illustrate a swapper 230 with a gear assembly 250, the swapper 230 may be of another suitable design. For example, the swapper 230 may include one or more band or pulley systems used to actuate the arms 241, 242 to swap the substrates 205. FIGS. 7A-7B illustrate an exemplary embodiment of a pulley-type swapper.

FIGS. 4A-4G are plan views of exemplary embodiments of a cluster tool. FIGS. 4A-4G show different configurations of the slit valves 214 between the processing chamber 110 and the swapper assembly 120, first slit valves 271 between the load locks 170 and factory interface 102, and second slit valves 272 between the swapper assembly 120 and the load locks 170. Additionally, FIGS. 4A-4G illustrate different configurations in the architecture of the cluster tool, namely the grouping of one or more components into a monolithic structures or in pairs. The motor assembly 260 and lift 275 are omitted in FIGS. 4A-4G. While FIGS. 4A-4G each only illustrate a cluster tool that includes one processing mainframe, a cluster tool could include more than one processing mainframe, as illustrate in FIG. 1B.

FIG. 4A illustrates the cluster tool 100 that is shown in FIGS. 1A and 2B. The swappers 230 are shown in a retracted position within the swapper assembly 120. As shown, the first slit valve 271 is disposed between each load lock 170 and the factory interface 102. A second slit valve 272 is disposed between each load lock 170 and the swapper assembly 120. A slit valve 214 is disposed between each processing chamber 110 and the swapper assembly 120. Thus, there are 12 separate slit valves that must be installed, actuated, and maintained.

Additionally, as shown in FIG. 4A, the cluster tool 100 has three separate monolithic structures that are assembled together and attached to the factory interface 102 to form the cluster tool 100. The four processing chambers 110 are part of the monolithic processing chamber structure 110a, as the four processing chambers 110 are integrated into the same housing 211. The swapper assembly 120 is part of the monolithic swapper assembly structure 120a, as all four swappers 230 are disposed in the same housing 222 rather than being separated into different housings. The load locks 170 are part of the monolithic load lock structure 170a, as all four of the load locks 170 are integrated into the same housing 274. The monolithic swapper assembly structure 120a is disposed between the monolithic processing chamber structure 110a and the monolithic load lock structure 170a.

FIG. 4B illustrates a cluster tool 400b. Cluster tool 400b includes similar components of cluster tool 100 without reciting the description of the components of the cluster tool 100 for brevity. The swappers 230 are shown in a retracted position within the swapper assembly 120.

As shown, a first slit valve 271 is disposed between the factory interface 102 and each load lock 170. A second slit valve 272 is disposed between a pair of load locks 170 and the swapper assembly 120. Thus, the second slit valves 272 are sized to span the openings in two load locks 170. A slit valve 214 is disposed between a pair of processing chamber 110 and the swapper assembly 120. Thus, the slit valves 214 are sized to span two openings 213 formed in the housing 211. Four slit valves (e.g., slit valves 214, 272) disposed between the load locks 170 and the processing chambers 110 need to open to facilitate swapping of the substrate 205 with the swappers 230 and closed to facilitate processing of the substrates 205 in the processing chamber 110.

Cluster tool 400b has eight, rather than twelve, separate slit valves that must be installed, actuated, and maintained. Reducing the number of slit valves reduces the number of actuators needed to open the valves. Decreasing the number of slit valves decreases manufacturing and maintenance costs.

FIG. 4B also illustrates the processing mainframe coupled to the factory interface 102 as a single monolithic structure. In other words, the processing chambers 110, swappers 230, and load locks 170 are integrated into a single housing, such that the housing 211 of the processing chambers 110, the housing 222 of the swapper assembly 120, and the housing 274 of the load locks 170 are integral with one another. Forming the processing mainframe from a single monolithic structure (e.g., single block) reduces manufacturing costs and also reduces and/or eliminates the need for seals between the interfaces of the load locks 170 with the swapper assembly 120 and the interfaces of the processing chambers 110 with the swapper assembly 120.

FIG. 4C illustrates a cluster tool 400c. Cluster tool 400c includes similar components of cluster tool 100 without reciting the description of the components of the cluster tool 100 for brevity. The swappers 230 are shown in a retracted position within the swapper assembly 120.

As shown, a first slit valve 271 is disposed between the factory interface 102 and each load lock 170. One second slit valve 272 is disposed each load lock 170 and the swapper assembly 120. One slit valve 214 is disposed between each processing chamber 110 and the swapper assembly 120. The slit valves 214 are sized to span four openings 213 formed in the housing 211. Similarly, the second slit valves 272 are sized to span the openings in four load locks 170. Thus, two slit valves disposed between the load locks 170 and the processing chambers 110 need to open to facilitate swapping of the substrate 205 with the swappers 230 and closed to facilitate processing of the substrates 205 in the processing chamber 110.

Cluster tool 400c has six, rather than twelve or eight, separate slit valves that must be installed, actuated, and maintained. Further reducing the number of slit valves reduces the number of actuators needed to open the valves. Further decreasing the number of slit valves decreases manufacturing and maintenance costs.

FIG. 4C also illustrates the processing mainframe coupled to the factory interface 102 as a two monolithic structure. The processing chambers 110 are integrated into a first housing, shown as monolithic processing chamber structure 110a. The swappers 230 and load locks 170 are integrated into a second housing shown as the second monolithic structure 401c, such the housing 222 of the swapper assembly 120 and the housing 274 of the load locks 170 are integral with one another. Forming the processing mainframe from a two monolithic structure reduces manufacturing costs and also reduces and/or eliminates the need for seals between the interfaces of the load locks 170 with the swapper assembly 120.

FIG. 4D illustrates a cluster tool 400d. Cluster tool 400d includes similar components of cluster tool 100 without reciting the description of the components of the cluster tool 100 for brevity. The swappers 230 are shown in a retracted position within the swapper assembly 120.

As shown, a first slit valve 271 is disposed between the factory interface 102 and each load lock 170. A second slit valve 272 is disposed between a pair of load locks 170 and the swapper assembly 120. A slit valve 214 is disposed between a pair of processing chambers 110 and the swapper assembly 120. The slit valves 214 are sized to span two openings 213 formed in the housing 211. Similarly, the second slit valves 272 are sized to span the openings in two load locks 170. Thus, four slit valves disposed between the load locks 170 and the processing chambers 110 need to open to facilitate swapping of the substrate 205 with the swappers 230 and closed to facilitate processing of the substrates 205 in the processing chamber 110.

Cluster tool 400d has eight, rather than twelve, separate slit valves that must be installed, actuated, and maintained. Reducing the number of slit valves reduces the number of actuators needed to open the valves. Decreasing the number of slit valves decreases manufacturing and maintenance costs.

FIG. 4D illustrate the processing mainframe as including a monolithic processing chamber structure 110a and a plurality of swapper assemblies 120 and load lock assemblies 470. As shown, the cluster tool 400d includes two swapper assemblies 120, each of which include two swappers 230. Each swapper assembly 120 has a separate housing 222. Each swapper assembly 120 may be operated by a separate motor assembly 260, or both swapper assemblies 120 may be operated by a single motor assembly 260.

The cluster tool 400d includes two load lock assembles 470 which include two load locks 170 integrated into the same housing 474. Each load lock assembly 470 is attached to one side of a swapper assembly 120 while part of the monolithic processing chamber structure 110a is attached to the other side of the swapper assembly 120. Thus, each second slit valve 272 is disposed between one of the two swapper assemblies 120 and one of the two load lock assemblies 470. Each slit valve 214 is also disposed between one of the two swapper assemblies 120 and the monolithic processing chamber structure 110a.

The cluster tool 400d, therefore, has one monolithic processing chamber structure 110a connected to a pair of swapper assemblies 120 and load lock assemblies 470.

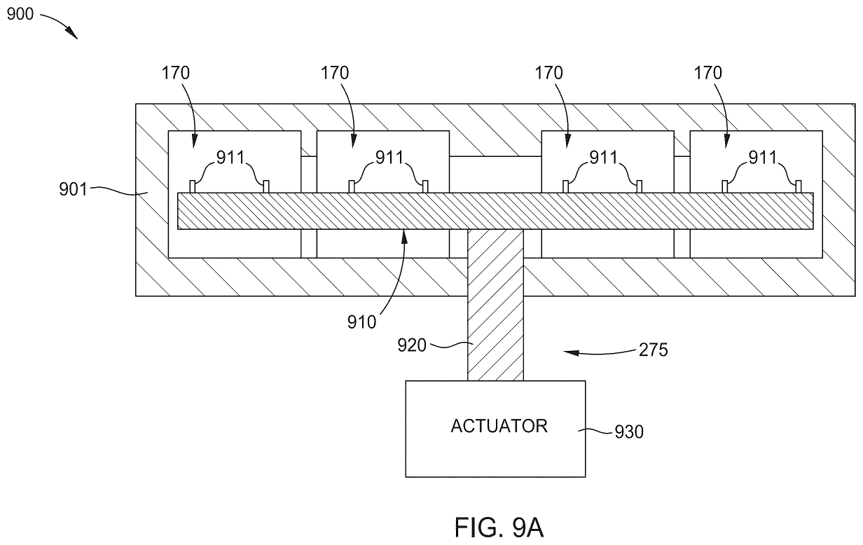

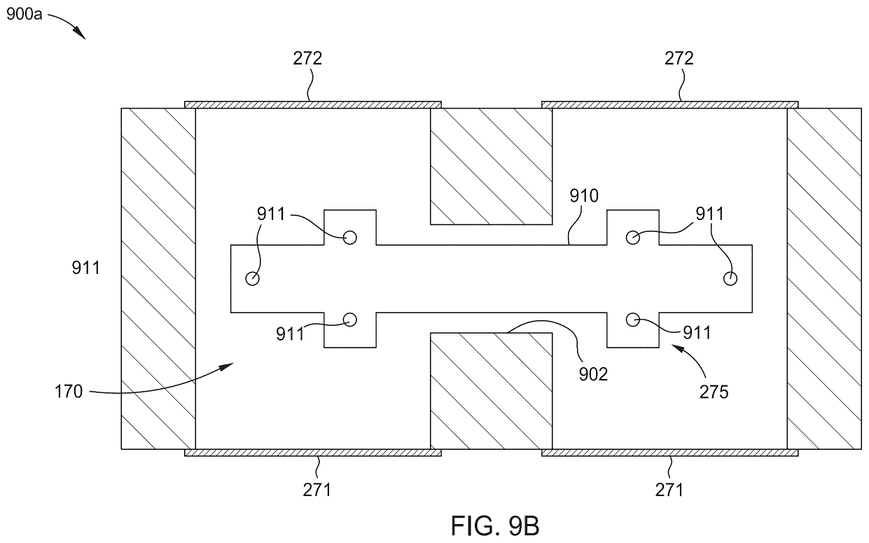

In some embodiments, each load lock assembly 470 includes a lift assembly, such as a lift 275 (FIG. 2A), that has two sets of three lift pins so that the lift 275 can simultaneously move and/or support a substrate in both of the load locks 170 of each of the load lock assemblies 470. In another embodiment, as shown in FIGS. 9A-9B and discussed further below, a single lift assembly can be adapted to simultaneously move and support four substrates in four separate chambers, such as four load lock chambers, by use of a lift plate 910 that includes four sets of three lift pins 911. However, one skilled in the art would understand that in some configurations a single lift assembly can also be configured to simultaneously move and support two or more substrates in two or more chambers simultaneously.

FIG. 4E illustrates a cluster tool 400e. Cluster tool 400e includes similar components of cluster tool 100 without reciting the description of the components of the cluster tool 100 for brevity. The swappers 230 are shown in a retracted position within the swapper assembly 120.

As shown, a single first slit valve 271 is disposed between the factory interface 102 and each load lock 170. A single second slit valve 272 is disposed between each load lock 170 and the swapper assembly 120. A single slit valve 214 is disposed each processing chamber 110 and the swapper assembly 120. The slit valves 214 are sized to span four openings 213 formed in the housing 211. Similarly, the first and second slit valves 271, 272 are sized to span the openings in four load locks 170. Thus, two slit valves disposed between the load locks 170 and the processing chambers 110 need to open to facilitate swapping of the substrate 205 with the swappers 230 and closed to facilitate processing of the substrates 205 in the processing chamber 110. Additionally, only one slit valve 271 is opened to place or remove a substrate from each load lock 170 and closed to allow the pressure within the load lock 170 to be reduced and/or isolate the interior of the cluster tool 400e from the atmosphere.

Cluster tool 400e has three, rather than twelve, eight, or six, separate slit valves that must be installed, actuated, and maintained. Further reducing the number of slit valves reduces the number of actuators needed to open the valves. Further decreasing the number of slit valves decreases manufacturing and maintenance costs. Additionally, as shown in FIG. 4E, the cluster tool 400e has three separate monolithic structures that are assembled together and attached to the factory interface 102 to form the cluster tool 100. The four processing chambers 110 are part of the monolithic processing chamber structure 110a, as the four processing chambers 110 are integrated into the same housing 211. The swapper assembly 120 is part of the monolithic swapper assembly structure 120a, as all four swappers 230 are disposed in the same housing 222 rather than being separated into different housings. The load locks 170 are part of the monolithic load lock structure 170a, as all four of the load locks 170 are integrated into the same housing 274. The monolithic swapper structure assembly 120a is disposed between the monolithic processing chamber structure 110a and the monolithic load lock structure 170a.

FIG. 4E also shows an exemplary arrangement of a plurality of heat sources of the heater assembly 178 that may be incorporated into any of the cluster tools 100, 400b, 400c, 400d, and 400e. As shown, there is a first plurality of heat sources 481 arranged in a first pattern and a second plurality of heat sources 482 arranged in a second pattern. As shown, the first pattern and second pattern are generally circular patterns, with the second plurality of heat sources 482 being arranged in the second pattern that is concentric with the first pattern of the first plurality of heat sources 481.

FIG. 4F illustrates a cluster tool 400f. Cluster tool 400f includes similar components of cluster tool 100 without reciting the description of the components of the cluster tool 100 for brevity. The swappers 230 are shown in a retracted position within the swapper assembly 120.

As shown, a first slit valve 271 is disposed between the factory interface 102 and each load lock 170. A second slit valve 272 is disposed between each load locks 170 and the swapper assembly 120. A slit valve 214 is disposed between each processing chambers 110 and the swapper assembly 120. Thus, eight slit valves that are adjacent to and in direct communication with the swapper assembly 120 (i.e., slit valves 214 and 272) need to open to facilitate swapping of the substrate 205 with the swappers 230 and closed to facilitate processing of the substrates 205 in the processing chamber 110.

FIG. 4F illustrates a processing mainframe that includes a monolithic processing chamber structure 110a and a plurality of swapper assemblies 120 and load lock assemblies 470. As shown, the cluster tool 400f includes two swapper assemblies 120, each of which include two swappers 230. Each swapper assembly 120 has a separate housing 222. Each swapper 230 in each swapper assembly 120 may be operated by a separate motor assembly 260, both swappers 230 in each swapper assembly 120 may be operated by a motor assembly 260, or the swappers 230 in both swapper assemblies 120 may be operated by a single motor assembly 260.

The cluster tool 400f includes two load lock assembles 470 which include two load locks 170 integrated into the same housing 474. Each load lock assembly 470 is attached to one side of a swapper assembly 120 while part of the monolithic processing chamber structure 110a is attached to the other side of the swapper assembly 120. Thus, each second slit valve 272 is disposed between one of the two swapper assemblies 120 and one of the two load lock assemblies 470. Each slit valve 214 is also disposed between one of the two swapper assemblies 120 and the monolithic processing chamber structure 110a.

The cluster tool 400f, therefore, has one monolithic processing chamber structure 110a connected to a pair of swapper assemblies 120 and load lock assemblies 470.

FIG. 4G illustrates a cluster tool 400g. Cluster tool 400g includes similar components of cluster tool 100 without reciting the description of the components of the cluster tool 100 for brevity. The swappers 230 are shown in a retracted position within the swapper assembly 120.

As shown, a first slit valve 271 is disposed between the factory interface 102 and a pair of load locks 170. In other words, a pair of load locks 170 share one first slit valve 271. A second slit valve 272 is disposed between a pair of load locks 170 and the swapper assembly 120. A slit valve 214 is disposed between each processing chambers 110 and the swapper assembly 120. The second slit valves 272 are sized to span the openings in two load locks 170. Eight slit valves are disposed between the load locks 170 and the processing chambers 110 that each need to be opened to facilitate swapping of the substrate using the swappers 230 and closed to facilitate processing of the substrates in the processing chambers 110.

Cluster tool 400g has eight, rather than twelve, separate slit valves that must be installed, actuated, and maintained. Reducing the number of slit valves reduces the number of actuators needed to open the valves. Decreasing the number of slit valves decreases manufacturing and maintenance costs.

FIG. 4G also illustrates a processing mainframe that includes a monolithic processing chamber structure 110a and a plurality of swapper assemblies 120 and load lock assemblies 470. As shown, the cluster tool 400g includes two swapper assemblies 120, each of which include two swappers 230. Each swapper assembly 120 has a separate housing 222. In some embodiments, each swapper 230 of each swapper assembly 120 may be operated by a separate motor assembly 260, or both swappers 230 in each swapper assemblies 120 may be operated by a single motor assembly 260.

The cluster tool 400G includes two load lock assembles 470 which include two load locks 170 integrated into the same housing 474. Each load lock assembly 470 is attached to one side of a swapper assembly 120 while part of the monolithic processing chamber structure 110a is attached to the other side of the swapper assembly 120. Thus, each second slit valve 272 is disposed between one of the two swapper assemblies 120 and one of the two load lock assemblies 470. Each slit valve 214 is also disposed between one of the two swapper assemblies 120 and the monolithic processing chamber structure 110a.

The cluster tool 400g, therefore, has one monolithic processing chamber structure 110a connected to a pair of swapper assemblies 120 and load lock assemblies 470.

While FIGS. 4A-4G show different embodiments of the cluster tool, with different slit valve configurations and different architectural configurations, the slit valve configuration and/or architectural configuration for one embodiment could be swapped for another. For example, a processing chamber may include three slit valves like cluster tool 400e while having a single monolithic structure like cluster tool 400b.

The pumping system 181, gas panel 182, and power supply 183 are shared by each processing chamber 110. Communication between a processing chamber 110 and the pumping system 181, gas panel 182, and/or power supply 183 may be stopped and started, such as by opening or closing a valve or opening or closing a switch. This selective communication between a resource (e.g., pumping system 181, gas panel 182, and power supply 183) allows the resource to be conserved when one or more of the processing chambers 110 does not need the resource. Additionally, the selective communication also allows the resource to be used by one or more processing chambers 110 while one or more other processing chambers 110 are not using the resource.

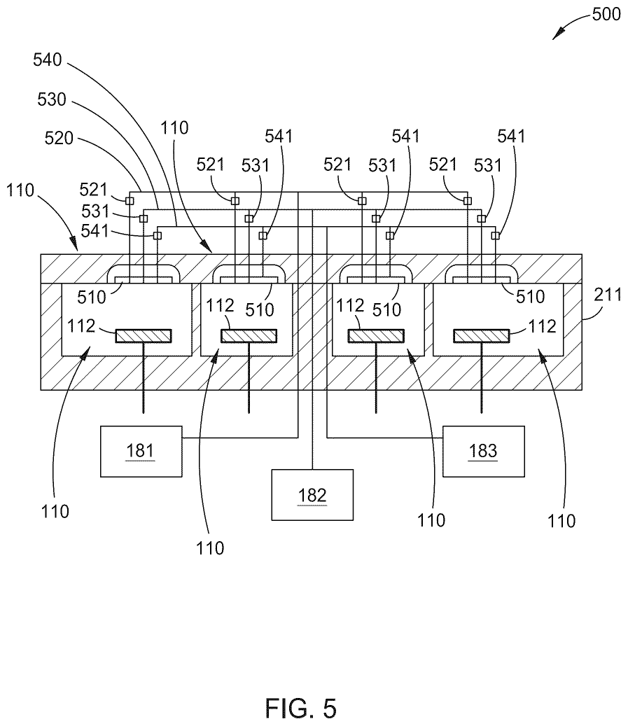

FIG. 5 illustrates a schematic cross-sectional view of the cluster tool 100 to illustrate the resource sharing by the processing chambers 110. As shown, the processing chambers 110 are contained are part of a monolithic processing chamber structure 500. Each processing chamber 110 includes the substrate support 112 and a shower head 510, which may be part of a source assembly. The shower head 510 is disposed at the top of the processing chamber 110 above the substrate support 112 and is configured to distribute one or more process gases onto a substrate supported on the substrate support 112. For example, the shower head may be used to perform a CVD process and or an ALD process.

The pumping system 181 may have a line 520 with one inlet connected to the one or more pumps and four outlets that connect to each processing chamber 110. One or more valves 521 that correspond to a processing chamber 110 may be used to selectively close communication between the one or more pumps of the pumping system 181 and one or more of the processing chambers 110 if evacuation is not needed to allow the pumping system 181 to continue to create or maintain a pressure in the other processing chambers 110. For example, one valve 521 may be closed while three of the valves 521 are open to allow communication between the pumping system 181 and three of the processing chambers 110. Each valve 521 may be controlled independently of one another.

The gas panel 182 may also have one line 530 that leads to all the processing chambers 110, with the line 530 having an outlet for each processing chamber 110. One or more valves or flow control devices 531 corresponding to a processing chamber 110 may be used to selectively close communication between the gas panel 182 and a processing chamber 110, such as closing communication to one processing chamber 110 that is not actively processing a substrate 205 while the gas panel 182 supplies gas to other processing chambers 110 that are actively processing a substrate 205. For example, the two valves 531 may be closed to prevent process gases from flowing into the two corresponding processing chambers 110 while the other two valves 531 may be opened to allow process gas to flow to the shower head 510 of the two corresponding processing chambers 110. Additionally, each valve 531 may be selectively controlled independently of one another to change (e.g., meter) the flow rate of the process gas into the corresponding processing chamber 110, such as varying the flow rate based on the progression of the process occurring within the processing chamber 110.

The power supply 183 is similarly shared by the processing chambers 110. One power line 540 may lead to the processing chamber 110. In some embodiments, a power line and a separate RF line are connected to the processing chamber 110. FIG. 5 shows the power line 540 as an RF supply line connected to the shower head 510 such that RF power is supplied to the shower head 510 during processing of the substrate.

One or more switches or metering devices 541 corresponding to each processing chamber 110 are connected to the power line 540. Each switch or metering device 541 may be used to selectively adjust or stop the flow of power from the power supply 183 to the processing chamber 110. For example, the switches or metering devices 541 of two processing chambers 110 may disconnect the processing chambers 110 from the power supply 183 while the switches or metering devices 541 of the other two processing chambers 110 allow the power supply 183 to supply power. Each switch or metering device 541 is operable independently from one another and can selectively adjust the power, such as RF power, supplied to the associated processing chamber 110.

In some embodiments, the pumping system 181 and power supply 183 may be shared with the load locks 170 and the swapper assembly 120. For example, the line 520 may also extend to each load lock 170 and to the swapper assembly 120. A valve 521 may similarly be included in the line 520 to selectively open or close communication between each load lock 170 and the pumping system 181 and selectively open or close communication between the swapper assembly 120 and pumping system 181.

For example, the power supply 183 may be used to selectively power the motor 261 of the motor assembly 260 to operate the swappers 230. A switch or metering device may be disposed between the swapper assembly 120 and the power supply 183 to selectively adjust or stop the flow of power to the motor(s) 261, such as stopping the supply of power when the swappers 230 are in the retracted position while the substrates 205 are processed in the processing chambers 110. Additionally, the power supply 183 may be used to supply power to the lift 275 and/or to heating elements disposed in the load lock 170 and/or swapper assembly 120. The power supply 183 may also be shared with the slit valves 214, 271, 272, such as being supplied to the slit valve actuator(s) when the slit valves 214, 271, 272 need to be opened or closed.

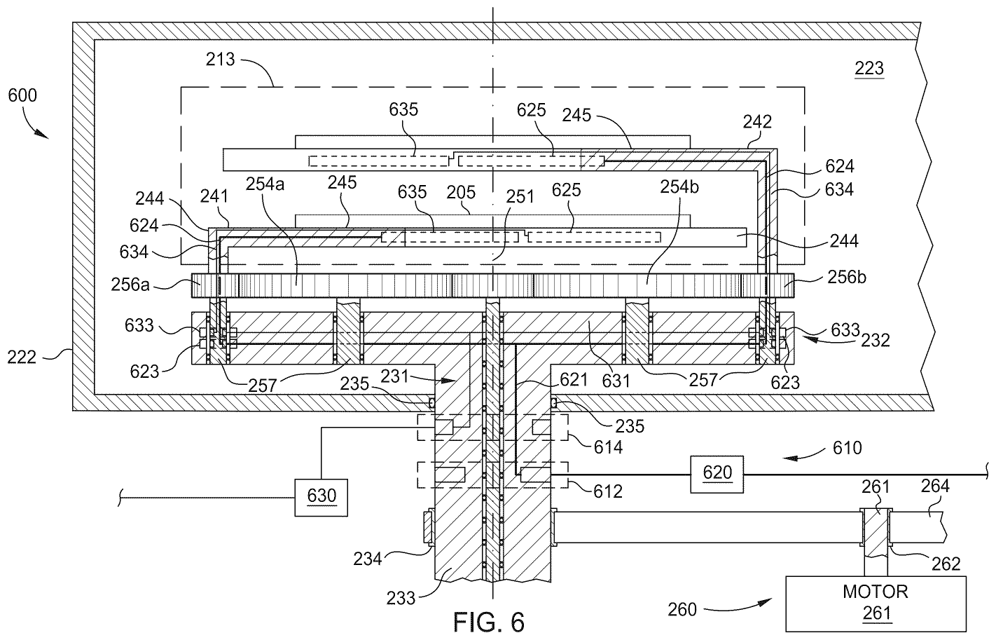

FIG. 6 illustrates a schematic partial cross-sectional view of a swapper assembly 600 which may be substituted for the swapper assembly 120 of any of the cluster tools 100, 400b, 400c, 400d, and 400e. The swapper assembly 600 has similar components as the swapper assembly 120 as indicated by the reference signs without reciting the description of these components of the swapper assembly 120 for brevity.

The blade 244 of the arms 241, 242 of the swappers 230 of the swapper assembly 600 include an electrostatic chuck to keep the substrate 205 engaged in a desired position on the support surface 245 as the arms 241, 242 are swapped between the load lock 170 and the processing chamber 110. The electrostatic chuck may include a monopolar, dipolar, or multi-polar chuck. The blade 244 of each arm 241, 242 is made of a dielectric material or semi-conductive ceramic material across which an electrostatic clamping field can be generated. Semi-conductive ceramic materials, such as aluminum nitride, boron nitride, or aluminum oxide doped with a metal oxide, for example, may be used to enable Johnsen-Rahbek or non-Coulombic electrostatic clamping fields to be generated.

FIG. 6 illustrates an exemplary el chuck assembly 610. The electrostatic chuck assembly 610 includes a first power source 620 configured to apply a first voltage to a first electrode 625 embedded in the blade 244 of each arm 241, 242. The electrostatic chuck assembly 610 further includes a second power source 630 to apply a second voltage to a second electrode 635 embedded in the blade 244 of each arm 241, 242. The second voltage is biased relative to the first voltage. The first power source 620 and second power source 630 may receive electrical power from the power supply 183 (FIGS. 1A-1B). The electrostatic chuck assembly 610 further includes a first rotary electrical connector 612 and a second rotary electrical connector 614 coupled to the shaft 233. The electrostatic chuck assembly 610 further includes a third rotary electrical connector 623 and a fourth rotary electrical connector 633 coupled to the upper portion 232. The first rotary electrical connector 612, the second rotary electrical connector 614, the third rotary electrical connector 623, and the fourth rotary electrical connector 633 may each be a slip ring having a plurality of brush connections or a roll ring connector.

The first electrode 625 and second electrode 635 transfer a chuck voltage to the blade 244 to generate an electrostatic force that clamps the substrate 205 to the blade 244. The electrostatic chuck assembly 610 is bipolar because the first electrode 625 and the second electrode 635 are electrically biased relative to one another. For example, the first power source 620 may supply a current with a positive voltage to the first electrode 625 while the second power source 630 may supply a current with a negative voltage to the second electrode 635 to generate a clamping force that chucks the substrate 205 to the blade 244. When desired to de-chuck the substrate 205 from the blade 244, the first power source 620 may supply a different current with a negative voltage to the first electrode 625 and the second power source 630 may supply a different current with a positive voltage to the second electrode 635.

Electrical power from the first power source 620 is supplied to the first rotary electrical connector 612. The electrical power is then transferred from the first rotary electrical connector 612 to each third rotary electrical connector 623 by a first wire 621. The third rotary electrical connectors 623 are shown coupled to the shaft 257 of each arm gear 256a,b. Electrical power is transferred from each third rotary electrical connector 623 to the first electrode 625 in a corresponding arm 241, 242 by a second wire 624.

Electrical power from the second power source 630 is supplied to the second rotary electrical connector 614. The electrical power is then transferred from the second rotary electrical connector 614 to each fourth rotary electrical connector 633 by a third wire 631. The fourth rotary electrical connectors 633 are shown coupled to the shaft 257 of each arm gear 256a,b. Electrical power is transferred from each fourth rotary electrical connector 633 to the second electrode 635 in a corresponding arm 241, 242 by a fourth wire 634.

In some embodiments, each swapper 230 may have both an electrostatic chuck assembly 610 and a pre-heat assembly 310.

While FIG. 6 illustrates a swapper 230 with a gear assembly 250, the swapper 230 may be of another suitable design. For example, the swapper 230 may include one or more band or pulley systems used to actuate the arms 241, 242 to swap the substrates 205.

FIG. 7A illustrates an embodiment of a swapper assembly 700 that may be substituted for the swapper assemblies 120 of any of the cluster tools 100, 400b, 400c, 400d, and 400e. FIGS. 7A and 7B illustrate an exemplary pulley-type swapper 730 that may be substituted for the gear-type swapper 230 shown in the preceding figures.

FIG. 7A illustrates a schematic partial cross-sectional view of the swapper assembly 700 with the swapper 730 disposed therein. The swapper assembly 700 has similar components as the swapper assembly 120 as indicated by the reference signs without reciting the description of these components of the swapper assembly 120 for brevity. The swapper 730 has similar components as the swapper 230 as indicated by the reference signs without reciting the description of these components of the swapper 730 for brevity. Each swapper 730 is operable to swap substrates along the trajectory 246 between the load lock 170 and the processing chamber 110.

Each swapper 730 includes a base 731 (e.g., body), an arm assembly 240, and a pulley system 750. The base 731 includes an interior chamber 734 partially defined by walls 735 of the base 731. The pulley system 750 is at least partially disposed within the interior chamber 734 of the base 731. The pulley system 750 is operable to move the arms 241, 242. The arm assembly 240 is supported by the base 731. The base 731 may be connected to a first shaft 762 of a motor assembly 760. A motor 761 of the motor assembly 760 rotates the first shaft 762 about a central axis 732 of the swapper 730, thereby rotating the base 731 about the central axis 732. In some embodiments, one or more seals may be disposed around the first shaft 762 to seal the swapper chamber 223 from the outside environment while facilitating the rotation of the base 731 relative to the housing 222.

FIG. 7B illustrates a partial exploded view of the swapper 730 to show the interconnection of the exemplary pulley system 750 with other select components of the swapper 730. The exemplary pulley system 750 shown in FIG. 7B includes a central pulley 751, a first belt 753, a second belt 754, a first elbow pulley 756a, and a second elbow pulley 756b. The first arm 241 is attached to the first elbow pulley 756a and the second arm 242 is attached to the second elbow pulley 756b. In some embodiments, the central pulley 751 is in a fixed position (e.g., stationary). For example, the central pulley 751 may be fixed on a second shaft 763 (FIG. 7A) that extends into the interior chamber 734 through an opening in the walls 735 of the base 731 and through an opening of the first shaft 762. The motor assembly 760 (FIG. 7A) may include one or more bearing elements to facilitate the rotation of the base 731 and the first shaft 762 relative to the second shaft 763.

The central pulley 751 is shown as a multi-level pulley, in that the central pulley 751 accommodates both the first belt 753 and the second belt 754. Each level of the central pulley 751 may include a groove to engage the respective belt 753, 754. The elbow pulleys 756a,b are shown as single-level pulleys to guide a respective belt 753, 754. As shown, the second belt 754 is positioned above the first belt 753. The first belt 753 is wrapped around the first level of the central pulley 751 and the first elbow pulley 756a while second belt 754 is wrapped around the second level of the central pulley 751 and the second elbow pulley 756b.

In some embodiments, the first belt 753 and second belt 754 may each be at a desired tension during operation of the swapper 730 to facilitate the movement of the arms 241, 242. In some embodiments, the first belt 753 and second belt 754 each have an in-line tensioner 755 to maintain the tension of the belt. The in-line tensioner 755 is fixed to both ends of the corresponding belt 753, 754. The in-line tensioner 755 may be adjusted to apply a desired tension the corresponding belt 753, 754. In some embodiments, the corresponding belt 753, 754 may be stretched to a desired tension and then each end of the corresponding belt 753, 754 is fastened to the tensioner to hold the belt in tension.

The pulley system 750 may alternative have four bands instead of two belts wrapped around the central pulley 751 and a respective elbow pulley 756a,b. A first end of each band is anchored to the respective elbow pulley 756a,b and the second end of each band is anchored to the central pulley. For example, a first band may be anchored at one end to the first level of the central pulley 751 and the other end is anchored to a first level of the first elbow pulley 756a. A second band may be anchored to the second level of the central pulley 751 at one end and the other end of the second band is anchored to a second level of the first elbow pulley 756a. A third and fourth band may be anchored to the second elbow pulley 756b and the central pulley 751 in a similar manner. Each band may have an in-line tensioner 755.

Each arm 241, 242 has a shaft 757. The shaft 757 of the first arm 241 is attached to the first elbow pulley 756a and the shaft 757 of the second arm 242 is attached to the second elbow pulley 756b. For example, the shaft 757 of each arm may be attached to an outer race of the respective elbow pulley 756a,b. The first elbow pulley 756a, and thus the first arm 241, rotates about a first elbow axis 749a. The second elbow pulley 756b, and thus the second arm 242, rotates about a second elbow axis 749b.

Each of the elbow pulleys 756a,b may include bearing elements 758 (FIG. 7A) to facilitate the rotation of the shaft 757, and thus the respective arm 241, 242, relative to the base 731. For example, an inner race of each elbow pulley 756a,b may be mounted on a mounting shaft 736 of the base 731. An outer race is engaged with the respective belt 753, 754. The bearing elements 758 allow an outer race of each pulley 756a,b to rotate relative to the inner race.

FIG. 7A shows the motor assembly 760 connected with one swapper 730. The motor assembly 760 extends through the lower wall of the housing 222. The motor assembly 760 includes a motor 761 that rotates first shaft 762. The motor assembly 760 may include seals between components to prevent in inflow of gases into the swapper chamber 223 through the motor assembly 760.

In some embodiments, as the base 731 rotates, the elbow pulleys 756a,b rotate (e.g., orbit) around the central pulley 751 which does not rotate. The first belt 753 causes the first elbow pulley 756a to rotate as the base 731 rotates relative to the central pulley 751, thereby rotating the first arm 241 about the first elbow axis 749a. Similarly, the second belt 754 causes the second elbow pulley 756b to rotate as the base 731 moves relative to the central pulley 751, thereby rotating the second arm 242 about the second elbow axis 749b.

In some embodiments, the motor assembly 760 includes a second motor 765 configured to rotate the second shaft 763 about the central axis 732 to rotate the central pulley 751. Thus, the central pulley 751 may be rotatable relative to the base 731 by the second motor 765 to cause the first and second elbow pulleys 756a,b, and thus the arms 241, 242 attached thereto, to rotate about the elbow axis 749a,b. The first motor 761 is selectively operated to rotate the base 731 about the central axis 732. The second motor 765 is selectively operated to rotate the central pulley 751 to rotate the arms 241, 242 relative to the base 731. The movement of the base 731 and arms 241, 242 are coordinated to move each arm 241, 242 along the desired trajectory 246.

In some embodiments, the ratio of the central pulley 751 to each elbow pulley 756a,b is configured to achieve a desired shape and resolution of the trajectory 246 (e.g., linear movement) in which the substrate 205 is transferred between the load lock 170 and processing chamber 110. In some embodiments, the central pulley 151 has a diameter twice the diameter of the elbow pulleys 756a,b (e.g., 2:1 ratio) to achieve the linear trajectory 246.

In some embodiments, the elbow pulleys 756a,b may have a non-circular profile, such as a cam profile to move the arm 241, 242 along the desired trajectory between the load lock 170 and processing chamber 110. For example, the desired trajectory 246 may be a trajectory that includes at least one linear segment and at least one non-linear segment. The non-linear segment may be an arcuate segment. The non-liner profile is configured to facilitate the movement of the center point 247 along the linear and non-linear segments of the trajectory 246.

As shown in FIG. 7A, a distance D1 extends from the central axis 732 to each elbow axis 749a,b. In other words, each elbow pulley 746a,b is positioned on the base 731 at the same distance (shown as D1) from the central axis 732. The distance between the center point 247 and respective elbow axis 749a,b of the first and second arm 241, 242 is shown as D2. In some embodiments, this distance D2 is the same as distance D1. The distances D1 and D2 may be selected based on the desired reach (e.g., distance between the central axis 732 and the center point 247 when the arms 241, 242 are extended) of the swapper 730.

In some embodiments, the distance D1 and distance D2 may be unequal. For example, the first distance D1 may be less than the second distance D1. The second distance D2 may be selected based on the depth of the processing chamber 110 such that the arms 241, 242 can reach into the processing chamber 110 to place the substrate 205 above the substrate support 212.

In some embodiments, the substrate 205 may not be centered above the center point 247 of an arm 241, 242. In some embodiments, the distances D1 and D2 are selected to allow the swapper 730 to align the center of the substrate 205 within the processing chamber 110 and/or load lock 170.

In some embodiments of the swapper 730, the arms 241, 242 may include the engagement members, such as engagement members 243 described above and shown in FIG. 2B.

In some embodiments of the swapper 730, the blade 244 of each arm 241, 242 may include a pocket 340 as described above and shown in FIG. 3. In some embodiments, the swapper 730 may include a pre-heat assembly, such as pre-heat assembly 310 described above and shown in FIG. 3. For example, each arm 241, 242 may include heating elements 318 disposed within. Rotary electrical connections, such as slip rings, may be used to transfer electrical power to the heating elements 318, such as slip rings within the outer race of the elbow pulleys 756a,b.

In some embodiments, the swapper 730 may include an electrostatic chuck to keep the substrate 205 engaged in a desired position on the support surface 245 as the arms 241, 242 are swapped between the load lock 170 and the processing chamber 110. The electrostatic chuck may include a monopolar, dipolar, or multi-polar chuck. The blade 244 of each arm 241, 242 is made of a dielectric material or semi-conductive ceramic material across which an electrostatic clamping field can be generated. Semi-conductive ceramic materials, such as aluminum nitride, boron nitride, or aluminum oxide doped with a metal oxide, for example, may be used to enable Johnsen-Rahbek or non-Coulombic electrostatic clamping fields to be generated. In some embodiments, the swapper 730 may an electrostatic chuck assembly 610, such as electrostatic chuck assembly 610 described and shown in FIG. 6. For example, the first and second arm 241, 242 may include a first electrode 625 and a second electrode 635. Rotary electrical connections, such as slip rings, may be used to transfer electrical power to the electrodes 625, 635, such as slip rings within the outer race of the elbow pulleys 756a,b.

In some embodiments, the swapper assembly 700 may include heat sources disposed in the swapper chamber 223, such as heat sources 280 described above and shown in FIG. 2B.

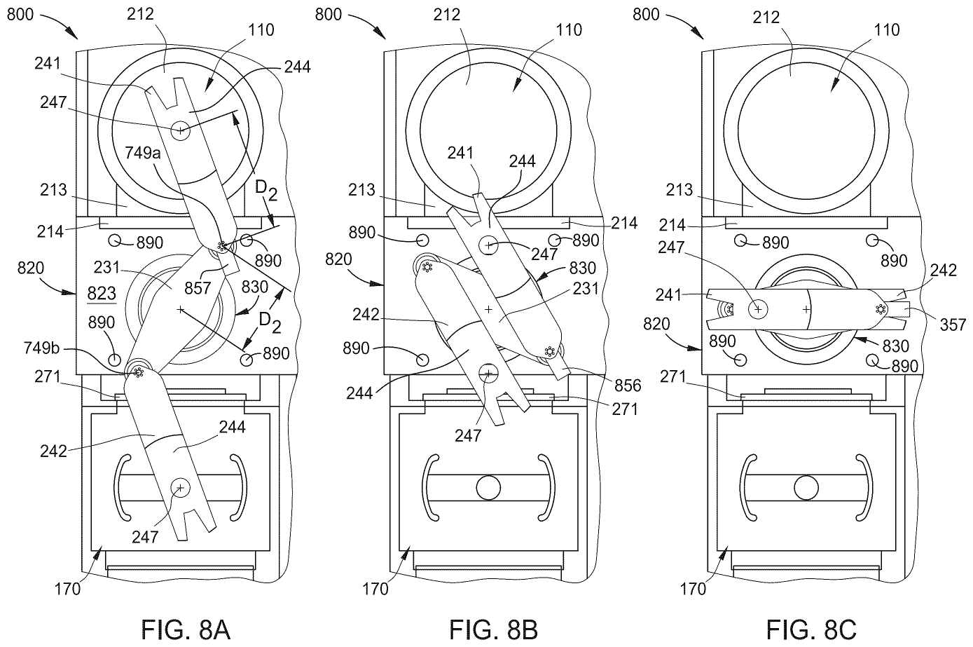

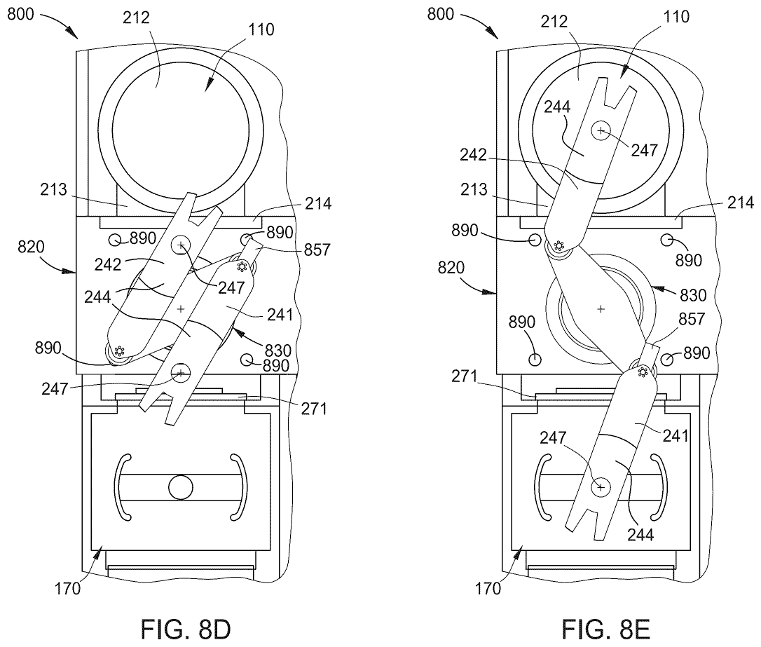

FIG. 8A-8E illustrates operation of a swapper 830 to swap substrates. While one swapper 830 is shown, a swapper 830 may be operated simultaneously with at least one other swapper 830. In one example, two or more swappers 830 may be operated simultaneously. As shown, the swapper assembly 830 is disposed between a processing chamber 110 and a load lock 170. The substrates are not shown on, the substrate supporting, swapper blades 244 coupled to the ends of the arms 241, 242 to facilitate discussion of the movement of the swapper 830.

FIG. 8A illustrates a schematic plan view of a cluster tool 800. The cluster tool 800 has similar components of cluster tool 100 as indicated by the reference signs without reciting the description of these components for brevity. As shown, the cluster tool 800 has a swapper assembly 820 substituted for the swapper assembly 120. The swapper assembly 820 has similar components as the swapper assembly 120. The swapper assembly 820 includes one or more swappers 830. The swapper 830 is similar to the swapper 730 and uses a pulley system, such as pulley system 750, to facilitate the movement of the arms 241, 242 to swap substrates.

The swapper 830 of cluster tool 800 similarly has a first distance D1 (shown in FIG. 8A) extending between the central axis (e.g., axis of rotation of the swapper 830) and the respective elbow axis 749a,b. The arms 241, 242 of swapper 830 similar have a second distance D2 (shown in FIG. 8A) extending between the center point 247 and the respective elbow axis 749a,b. The first distance D1 and second distance D2, however, are not equal. The first distance D1 is less than the second distance D1. In some embodiments, the second distance D2 may exceed the first distance D1 by more than 100 mm. The second distance D2 may be selected based on the depth of the process station 110 such that the arms 241, 242 can reach into the process station 110 to place the substrate above the substrate support 212.

The swapper 830 includes a shaft 857 coupled to the first arm 241 that is configured to allow the substrate disposed on the second arm 242 to pass through the first elbow axis 749a as it moves relative to the first arm 241. The shaft 857 of the first arm 241 may be a C-shaped member to allow the substrate on the second arm 242 to pass underneath the first arm 241 and to pass through the first elbow axis 749a without contacting the first arm 241.

FIG. 8A shows each of the arms 241, 242 in a first extended position, with the first arm 241 positioned in the processing station 110 and the second arm 242 positioned in the load lock 170 while the slit valves 214, 271 are open. At the end of a swapping operation, the swapper 830 is operated such that the first arm 241 is placed into the load lock 170 and the second arm 242 is placed into the processing station 110 as shown in FIG. 8E. The substrates disposed on each arm 241, 242 are moved along a trajectory, such as a linear or non-linear trajectory, as they are swapped by the swapper 830.

FIG. 8B illustrates the swapper 830 with the arms 241, 242 in a first intermediate position between the first extended position shown in FIG. 8A and the retracted position shown in FIG. 8C. The swapper 830 continues to move such that the arms 241, 242 are moved to the retracted position shown in FIG. 8C. The swapper 830 continues to move the arms 241, 242 from the retracted position to a second intermediate position, as shown in FIG. 8D. The swapper 830 continues to move the arms 241, 242 from the second intermediate position to a second extended position shown in FIG. 8E such that the first arm 241 is placed into the load lock 170 and the second arm 242 is placed into the processing chamber 110. The operation(s) of the swapper 830 can be reversed to return the arms 241, 242 to the first extended position.

In some embodiments, a plurality of sensors 890, such as through-beam or retroreflective type optical sensors, within the swapper assembly 820 are used to detect a position of one or both substrates as the substrates transit through the swapper assembly 820 on the swapper blades 244. The sensors 890 may monitor the motion of substrates to facilitate determining if the swapper 830 is deviating from a desired motion or substrate movement trajectory as the substrates are being swapped during a swapping process. The controller 190 may take corrective action based on a detected position of a substrate disposed on a respective arm 241, 242. For example, if the position detected by the sensors 890 show that a substrate's position or trajectory deviates from a desired position or trajectory, then the controller 190 may instruct a motor assembly controlling the swapper 830 to adjust the position of the respective arm 241, 242 such that the substrate will not collide with components within the system and/or be centered in the load lock 170 and/or processing chamber 110 at the end of a swapping process. In some embodiments, the position of the substrates is indicative of a deviation from a desired motion of the swapper 830. For example, the repeatability of the motion of the swapper 830 may be used to repeatedly place the substrate in a desired location, and a deviation in the desired motion indicates a malfunction and/or need for re-alignment. Thus, a detected deviation in the position of the substrate 830 may be used to diagnose that a swapper 830 needs to be repaired or realigned.

While sensors 890 are shown in FIGS. 8A-8E, the sensors 890 can be incorporated into any of the swapper assemblies (e.g., 120, 300, 600, 700) and cluster tools (e.g., 100, 100a, 400b, 400c, 400d, 400e, 400f, 400g) described herein.

FIG. 9A illustrates a schematic of a multiple chamber configuration, such as a load lock assembly 900, which includes four load locks 179, that includes a lift assembly that includes a lift 275. The load lock assembly 900 is shown having one monolithic housing for each of the load locks 170 of the load lock assembly 900. The lift 275 includes a lift plate 910, a shaft 920, and an actuator 930 that is configured to position the lift plate 910 within the chambers. The lift plate 910 is connected to the actuator 930 by the shaft 920. The actuator 930 translates the shaft 920 up or down to similarly translate the lift plate 910. In some embodiments, the actuator 930 is an electric actuator, a hydraulic actuator, or any suitable actuator.

The lift plate 910 extends into each of the load locks 170. In one example, as shown in FIG. 9B, the lift 275 may be used in a two load lock chamber configuration. Thus, FIG. 9B illustrates an alternative swapper assembly 900a which includes two load locks that share the lift 275. In this example, there may be a channel or opening formed between each of the load locks 170, such as opening 902 shown in FIG. 9B, to allow the lift plate 910 to move within both of the load locks 170. The lift plate 910 includes a set of lift pins 911 in each load lock 170. In some embodiments, each set of lift pins 911 includes three lift pins. A substrate may be transferred to a set of lift pins 911 within a load lock 170 by the robot 102a. Each adjacent swapper can be positioned such that an arm, such as arm 241, is positioned underneath the bottom surface of a substrate positioned on the lift pins 911 and above top surface of the lift plate 910. Actuator 930 is then used to lower the lift plate 910 to allow all of the supported substrates (e.g., four in FIG. 9A or two in FIG. 9B) to be transferred from the respective set of lift pins 911 to the respective swapper arm simultaneously. Similarly, the actuator 930 may be raised to transfer the supported substrates from the swappers to the respective set of lift pins 911 simultaneously.

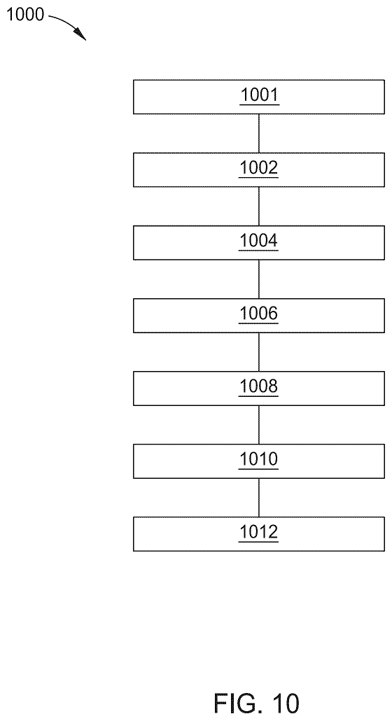

FIG. 10 illustrates a flow chart of an exemplary method 1000 of operating a cluster tool, such as cluster tool 100. This method 1000 can be occurring in multiple processing mainframes 101 of the cluster tool 100, such as cluster tool 100a, simultaneously. The exemplary method 1000 is, for example, applicable to swappers 230 (e.g., swappers shown in FIGS. 2B, 2C, 3, and 6), swapper 730, and swapper 830.

At operation 1001, a robot 102a of the factory interface 102 may place a substrate 205, such as a non-processed substrate, in the load lock 170 through the open first slit valve 271 prior to the swapper, such as swapper 230, swapper 730, or 830, placing an arm, such as the second arm 242, into the load lock 170. In other words, the non-processed substrate may be placed into the load lock 170 while the arms 241, 242 are in a retracted position. The substrate 205 may be placed on one or more support members, such as lift pins, within the load lock 170. In some embodiments, the lift pins are in the raised position when the robot 102a places the substrate into the load lock 170. The lift pins, for example, may be part of the lift 275. The robot 102a of the factory interface 102 may be used to align the center of the substrate 205 in a desired position within the load lock 170. This desired position may be selected based on the desired position of the center of the substrate 205 relative to the blade 244 when the substrate 205 is transferred to an arm 241, 242, such as the second arm 242. For example, the centers of the load lock 170 and processing chamber 110 may be slightly offset. The robot 102a of the factory interface 102 places the substrate 205 in position within the load lock 170 such that the center of the substrate 205, after being retrieved by the second arm 242, will be aligned with the center of the substrate support 212 when the second arm 242 is moved to the processing chamber 110. The load lock 170 is then least partially evacuated by the pumping system 181 while the first slit valve 271 and second slit valve 272 are closed to decrease the pressure within the load lock 170. For example, the pumping system 181 may be used to equalized pressure within the interior of the load lock 170 with the pressure within the swapper chamber 223.

In some embodiments of operation 1001, the heater assembly 178 may be activated. In some embodiments, the heater assembly 178 may be used to pre-heat the substrate 205. In some embodiments, the heater assembly 178 may be used for a degas operation. The pumping system 181 connected to each load lock 170 may be used to remove emissions from the substrate 205 during degassing.

In some embodiments, operation 1001 includes the robot 102a of the factory interface 102 removing a processed substrate from the lift pins of the load locks 170 through open first slit valves 271 prior to placing a non-processed substrate onto the lift pins.

At operation 1002, at least two swappers 230, 730, 830, such as four swappers, are operated such that each swapper 230 has a first arm 241 disposed in an extended position within a processing chamber 110 and a second arm 242 disposed in an extended position within a load lock 170. In some embodiments, every swapper 230, 730, 830 is operated simultaneously. The slit valves 214 are opened to accommodate the insertion of the first arm 242 into the processing chamber 110 and the slit valve 272 is opened to accommodate the movement of the second arm 242 into the load lock 170. The lift pins of the load lock 170 and lift pins within the processing chamber are moved to the raised position prior to the swapper 230, 730, 830 placing the respective arm into the load lock 170 and processing chamber 110.

At operation 1004, the substrate 205 positioned within the load lock 170 is then transferred to the blade 244 of the second arm 242. For example, the substrate 205 may be supported on lift pins within the load lock 170 that are lowered after the second arm 242 is placed in load lock 170 to transfer the substrate 205 onto the blade 244 of the second arm 242. The lift 275, such as the lift 275 shown in FIG. 9A, may be used to lower all the lift pins in each load lock 170 simultaneously. In some embodiments, where each load lock 170 has a different lift 275, each lift 275 is operated simultaneously to transfer each substrate 205 onto the blade 244 of a respective second arm 242. In some embodiments, there may be multiple lifts 275 that each move at least two substrates, such as having at least two of the lifts 275 shown in FIG. 9B.

The lift pins of a processing chamber 110 are lowered, such as being retracted, to lower a processed substrate 205 supported on the lift pins into engagement with the support surface 245 of the blade 244 of each first arm 241. The lift pins are raised, such as being raised with the lift plate 910, to lift the substrate 205 to a position above the substrate support 212 prior to operation 1002 to allow each first arm 241 to move below the raised substrate 205. The lift pins in each processing chamber 110 may be moved simultaneously. For example, the lift pins in each processing chamber 110 may be operated simultaneously to transfer each substrate 205 to a respective each first arm 241 in unison. In some embodiments, the lift pins in the processing chamber 110 are operated simultaneously with the lift 275 of the load locks 175. Operating the lift pins of each processing chamber 110 simultaneously with the lift pins, such as the lift 275, of the load locks 170 reduces the overall time spent transferring the substrates 205 to the respective arms 241, 242 of each swapper 230. In other words, operating the lift pins of each processing chamber 110 and each load lock 170 simultaneously increases the throughput of the substrates through the cluster tool, such as through cluster tool 100.

In some embodiments of operation 1004, the electrostatic chuck of the swapper 230, such as the electrostatic chuck assembly 610, is used to generate a clamping force to retain the substrates 205 on the substrate support surface 245 as the arms 241, 242 move. Operation 1004 may occur before, after, or simultaneously with operation 1002. Operation 1004 may take more or less time to complete than operation 1002.

At operation 1006, the swappers 230, 730, 830 are operated to swap the positions of the arms 241, 242, thereby moving the substrates 205 disposed thereon along the trajectory. For example, the swapper 230 may be operated to swap the substrates along the linear trajectory 246. For example, swapper 830 is operated as shown in FIGS. 8A-8E to move the substrate along a non-linear trajectory. Each of the swappers 230, 730, 830 may be operated simultaneously. For example, arms 241, 242 of every swapper 230, 730, 830 may reach the retracted position at the same time as the substrates are swapped along the trajectory 246. Each second arm 242 is now located in the corresponding processing chamber 110 while each first arm 241 is located in the corresponding load lock 170. The unprocessed substrate 205 on each second arm 242 may optionally be pre-heated as the position of the arms 241, 242 are swapped. In some embodiments, the processed substrate 205 on the first arm 241 may optionally be cooled as the positon of the arms 241, 242 are swapped. The slit valves 214 and 272 are open while the arms 241, 242 swap positions.

The controller 190 operates the swapper 230, 730, 830 to move the substrate 205 along a desired velocity and/or acceleration profile as the substrate 205 moves along the trajectory 246 during operation 1006. For example, the swapper 230, 730, 830 may be operated to move the substrate 205 at a constant or substantially constant speed along the entirety or a majority of the trajectory 246.

The sensors 890 may be used during the operation of the swapper 230, 730, 830 to monitor the position and/or trajectory of the substrates during a swapping process. The controller 190 may adjust the position and/or trajectory of the arms and substrates disposed on one or more of the swappers 230, 730, 830 if the position of one or both substrates on the swapper deviates from a desired positon, trajectory vector, desired velocity, and/or desired acceleration profile. Additionally, the controller 190 may use the data obtained from the sensors 890 to determine that a swapper 230, 730, 830 is malfunctioning and/or needs adjustment.

At operation 1008, each substrate 205 supported on the second arm 242 above the substrate support 212 within the processing chamber 110 is disengaged from the blade 244 by raising the lift pins. The movement of the lift pins can accommodate the difference in heights of the supports 244 of the arms 241, 242. Each substrate 205 supported on the first arm 241 is removed therefrom by raising the support members, such as lift pins, within the load lock 170. The lift pins of each load lock 170 may be operated simultaneously such that each substrate 205 in each load lock 170 is disengaged from the blade 244 of the second arm 242 in unison. For example, the lift 275 shown in FIG. 9A or FIG. 9B may be used to raise the lift pins to lift multiple substrates simultaneously. Similarly, the lift pins of each processing chamber 110 may be operated simultaneously such that each substrate 205 in each processing chamber 110 is disengaged from the blade 244 of the second arm 241 in unison. The lift pins in the load lock 170 and the lift pins in the processing chambers 110 may be moved simultaneously to increase the throughput of the cluster tool, such as cluster tool 100.

At operation 1010, the motor assembly 260 is operated to move the arms 241, 242 of each swapper 230, 730, 830 to the retracted position to facilitate processing of the substrates within the processing chambers 110. In some embodiments, each swapper 230, 730, 830 is operated simultaneously. The lift pins in the processing chamber 110 are lowered, such the lift pins in each processing chamber 110 being lowered simultaneously, to engage the substrate 205 with the substrate support 212. The substrate 205 is then processed within the processing chamber 110. The slit valves 214, 271, 272, may be closed while the substrate 205 is processed, such as closing the valves 271, 272 once the swapper 230, 730, 830 is clear. In some embodiments, operation 1010 includes opening the first slit valve 271 while the second slit valve 272 is closed, to allow a robot 102a of the factory interface 102 to retrieve the processed substrate 205 from the load lock 170. The robot 102a of the factory interface 102 then places the processed substrate 205 into a FOUP 103.

The method 1000 may repeat after operation 1010, with a new non-processed substrate may then be transferred to the load locks 170, such as being transfer to lift pins of a lift 275, by the robot 102a. Once the new non-processed substrate is within the load locks 170, the slit valves 271 are closed and then the load locks 170 are evacuated. The slit valves 271, 214 may later be opened to allow the swapper 230, 730, 830 is operated to position the second arm 242 back into the load lock 170 and to position the first arm 241 back into the processing chamber 110 after the substrate is processed while the substrate 205 is positioned above the substrate support 212 on lift pins. The new unprocessed substrate may be swapped for the processed substrate as described above.

In some embodiments, the swapper may not have a body 231 and a gear assembly 250 as shown in FIGS. 2A-2B, FIG. 3 and FIG. 6. Instead, the swapper may be a parallelogram linkage that is rotatable by the motor assembly 260 to swap the arms 241, 242.

In one embodiment, a swapper assembly includes a housing, at least two swappers, and a motor assembly. The at least two swappers are at least partially disposed within and rotatable relative to the housing. Each swapper includes a body, a first arm, a second arm, and wherein the first arm and second arm are rotatable relative to the body. The motor assembly includes a single motor configured to operate the at least two swappers simultaneously to change the position of the first arm and second arm.

In one embodiment, a method of operating a cluster tool includes placing a first substrate on a first arm of a first swapper, the first arm being positioned in a first load lock. The method further includes placing a second substrate on a second arm of the first swapper, the second arm being positioned within a first processing chamber. The method further includes placing a third substrate on a third arm of a second swapper, the third arm being located in a second load lock. The method further includes placing a fourth substrate on a fourth arm of the second swapper, the fourth arm being positioned within a second processing chamber. The method further includes operating the first swapper and the second swapper with a single motor to simultaneously move the first substrate on the first arm into the first processing chamber, the second substrate on the second arm into the first load lock, the third substrate on the third arm into the second processing chamber, and the fourth substrate on the fourth arm into the second load lock.

In one embodiment, a cluster tool includes a first load lock, a second load lock, a first processing chamber, a second processing chamber, and a swapper assembly. The swapper assembly is disposed between the first load lock and the first processing chamber and between the second load lock and the second processing chamber. The swapper assembly includes a housing, a first swapper, and a second swapper. The first swapper is at least partially disposed within the housing and is rotatable relative to the housing. The first swapper includes a first arm and a second arm, wherein the first arm is moveable to convey a first substrate disposed thereon along a first linear trajectory from the first load lock to the first processing chamber, and the second arm is moveable to convey a second substrate disposed thereon along a second linear trajectory from the first processing chamber to the first load lock. The second swapper is at least partially disposed within the housing and is rotatable relative to the housing. The second swapper includes a third arm and a fourth arm, wherein the third arm is moveable to convey a third substrate disposed thereon along a third linear trajectory from the second load lock to the second processing chamber, and the fourth arm is moveable to convey a fourth substrate disposed thereon along a fourth linear trajectory from the second processing chamber to the second load lock. The motor assembly includes one, and only one motor configured to operate the first swapper and second swapper simultaneously to move the first arm and second arm of the first swapper and the third arm and fourth arm of the second swapper.

In one embodiment, a cluster tool includes four load locks and four processing chamber separated by a swapper assembly. Each load lock is paired with a processing chamber across the swapper assembly. The swapper assembly includes four swappers, each swapper configured to swap a substrate between one pair of load locks and processing chambers. In some embodiments, the processing chambers are part of a monolithic structure connected to the swapper assembly and the load locks. In some embodiments, the load locks, swapper assembly, and processing chambers are part of one monolithic structure sharing the same housing. In some embodiments, the load locks, swapper assembly, and processing chambers are part of separate monolithic structures. In some embodiments of the cluster tool, the cluster tool includes multiple processing mainframes each processing mainframe including four load locks and four processing chamber separated by a swapper assembly.

While the foregoing is directed to embodiments of the present disclosure, other and further embodiments of the disclosure may be devised without departing from the basic scope thereof, and the scope thereof is determined by the claims that follow.

1. A cluster tool, comprising:
a factory interface;
a first processing mainframe coupled to the factory interface, including:
a processing chamber monolithic structure including four processing chambers in the same housing;
four load locks coupled to the processing chamber monolithic structure, each load lock including a heater assembly configured to increase the temperature of a substrate disposed in the load lock; and
a swapper assembly disposed between the four load locks and the processing chamber monolithic structure, wherein the swapper assembly includes four swappers, each swapper configured to swap substrates between one processing chamber and one load lock along a linear trajectory.

2. The cluster tool of claim 1, including a second processing mainframe coupled to the factory interface and disposed above the first processing mainframe.

3. The cluster tool of claim 1, further comprising:
a first slit valve spanning across openings of the four processing chambers; and
a second slit valve spanning across openings of the four load locks adjacent to the swapper assembly.

4. The cluster tool of claim 1, further comprising:
a first slit valve spanning across openings of a first pair of the four processing chambers;
a second slit valve spanning across openings of a second pair of the four processing chambers;
a third slit valve spanning across openings of a first pair of the four load locks adjacent to the swapper assembly; and
a fourth slit valve spanning across openings of a second pair of the four load locks adjacent to the swapper assembly.

5. The cluster tool of claim 1, further comprising:
a single motor to operate all four swappers.

6. The cluster tool of claim 1, further comprising:
a first motor to operate a first pair of the four swappers; and
a second motor to operate a second pair of the four swappers.

7. The cluster tool of claim 1, wherein each swapper is operated by a separate motor.

8. The cluster tool of claim 1, wherein the heater assembly include one or more lamps to generate heat.

9. The cluster tool of claim 1, wherein each swapper includes including a pocket to retain the substrate disposed therein as the substrate is swapped.

10. A swapper, comprising:
a body;
a first arm rotatable relative to the body, the first arm including a first support;
a second arm rotatable relative to the body, the second arm including a second support;
an electrostatic chuck assembly, including:
a first electrode disposed in the first support;
a second electrode disposed in the first support, wherein the first electrode and second electrode are configured to be energized to chuck a first substrate to the first support;
a third electrode disposed in the second support; and
a fourth electrode disposed in the second support, wherein the third electrode and fourth electrode are configured to be energized to chuck a second substrate to the second support.

11. The swapper of claim 10, the electrostatic chuck assembly further comprising:
a first power source configured to supply a first electric power to the first electrode and to the third electrode; and
a second power source configured to supply a second electric power to the second electrode and to the fourth electrode.

12. The swapper of claim 10, wherein:
the electrostatic chuck assembly further includes:
a first rotary electrical connector coupled to the first arm, the first rotary electrical connector configured to supply electrical power to the first electrode; and
a second rotary electrical connector coupled to the first arm, the second rotary electrical connector configured to supply electrical power to the second electrode.

13. The swapper of claim 12, wherein:
the electrostatic chuck assembly further includes:
a third electrode disposed in the second support;
a fourth electrode disposed in the second support;
a third rotary electrical connector coupled to the second arm, the third rotary electrical connector configured to supply electrical power to the first electrode; and
a fourth rotary electrical connector coupled to the second arm, the fourth rotary electrical connector configured to supply electrical power to the fourth electrode.

14. The swapper of claim 10, further comprising:
a first plurality of engagement members protruding from the first support of the first arm; and
a second arm rotatable relative to the body, the second arm including a second support and a second plurality of engagement members protruding from the second support, wherein the first plurality of engagement members and the second plurality of engagement members a surface roughness that exceeds 32 microinches.

15. The swapper of claim 14, wherein the surface roughness is between 45 microinches and 65 microinches.

16. A method of operating a cluster tool, comprising:
heating a first substrate disposed in a first load lock with one or more first heat sources;
heating a second substrate disposed in a second load lock with one or more second heat sources;
placing the first substrate on a first arm of a first swapper, the first arm being positioned in a first load lock;
placing the second substrate on a second arm of the first swapper, the second arm being positioned within a first processing chamber;
placing a third substrate on a third arm of a second swapper, the third arm being located in a second load lock;
placing a fourth substrate on a fourth arm of the second swapper, the fourth arm being positioned within a second processing chamber; and
operating the first swapper and the second swapper to simultaneously move the first substrate on the first arm into the first processing chamber along a first trajectory, the second substrate on the second arm into the first load lock along a second trajectory, the third substrate on the third arm into the second processing chamber along a third trajectory, and the fourth substrate on the fourth arm into the second load lock along a fourth trajectory.

17. The method of claim 16, wherein the first trajectory is parallel to the second trajectory.

18. The method of claim 16, further comprising:
removing the first substrate from the first arm in the first processing chamber and removing the third substrate from the third arm in the second processing chamber; and
operating the first swapper to move the first arm and the second arm to a retracted position simultaneously with operating the second swapper to move the third arm and fourth arm to a retracted position using the same motor.

19. The method of claim 16, further comprising:
suppling electric current to one or more electrodes in the first arm to chuck the first substrate to the first arm; and
supplying electric current to one or more electrodes in the second arm to chuck the second substrate to the second arm.

20. The method of claim 18, wherein the first substrate, second substrate, third substrate, and fourth substrate move at a constant speed along the respective trajectory.
